(19) United States
(12) Patent Application Publication
(10) Pub. No.: US 2015/0263290 A1
(43) Pub. Date: Sep. 17, 2015

(54) CONDENSED CYCLIC COMPOUND AND ORGANIC LIGHT-EMITTING DEVICE INCLUDING THE SAME

(71) Applicant: SAMSUNG DISPLAY CO., LTD., Yongin-City (KR)

(72) Inventors: Se-Jin Cho, Yongin-City (KR); Chang-Min Lee, Yongin-City (KR)

(21) Appl. No.: 14/340,442

(22) Filed: Jul. 24, 2014

(30) Foreign Application Priority Data
Mar. 11, 2014 (KR) 10-2014-0028599

(51) Int. Cl. H01L 51/00

(52) U.S. Cl. CPC H01L 51/0058; H01L 51/0067; H01L 51/0072; H01L 51/0065; H01L 51/5092

(57) ABSTRACT

A condensed cyclic compound is represented by Formula 1, and an organic light-emitting device includes the condensed cyclic compound.

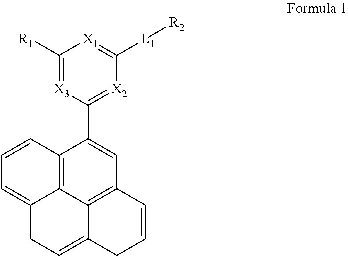

In Formula 1, X₁, X₂, X₃, L₁, R₁, and R₂ are already stated in the detailed description. An organic light-emitting device including an organic layer having the condensed cyclic compound has improved color change in a relatively low-gradation region.

### CROSS-REFERENCE TO RELATED APPLICATION

This application claims priority to and the benefit of Korean Patent Application No. 10-2014-0028599, filed on Mar. 11, 2014, in the Korean Intellectual Property Office, the disclosure of which is incorporated herein in its entirety by reference.

### BACKGROUND

1. Field

One or more embodiments relate to a condensed cyclic compound and an organic light-emitting device including the same.

2. Description of the Related Art

Organic light emitting devices are self-emission devices that have wide viewing angles, high contrast ratios, short response time, and excellent brightness, driving voltage, and response speed characteristics, and produce full-color images.

A typical organic light-emitting device has a structure including a substrate, and an anode, a hole transport layer, an emission layer, an electron transport layer, and a cathode sequentially stacked on the substrate. The hole transport layer, the emission layer, and the electron transport layer are organic thin films formed of organic compounds.

In typical organic light-emitting devices, the mobility of electrons is lower than that of holes, and thus, electrons and holes may less likely to meet and combine in the emission layer, leading to low emission efficiency. In addition, the energy band of the emission layer does not match with that of the electron transport layer. Accordingly, electrons may have difficulty to enter into the emission layer.

### SUMMARY

Aspects of one or more embodiments of the present invention are directed toward a material that provides good energy band matching and ease of electron supply to improve color change in a relatively low gradation region. Aspects of one or more embodiments of the present invention are directed toward a novel condensed cyclic compound for an organic light-emitting device (which improves color change in a relatively low-gradation region), and an organic light-emitting device including the novel condensed cyclic compound.

Additional aspects will be set forth in part in the description which follows and, in part, will be apparent from the description, or may be learned by practice of the presented embodiments.

According to one or more embodiments of the present invention, a condensed cyclic compound is represented by Formula 1 below:

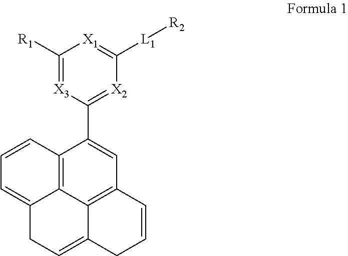

wherein in Formula 1,

X₁, X₂, and X₃ may be each independently N or —CH, and at least one of X₁, X₂, and X₃ may be N.

R₁ and R₂ may be each independently selected from a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group;

a C₁-C₄₀ alkyl group, a C₂-C₄₀ alkenyl group, a C₂-C₄₀ alkynyl group, and a C₁-C₄₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group.

L₁ may be selected from a direct bond; a C₆-C₄₀ arylene group; a C₂-C₄₀ heteroarylene group; and a C₆-C₄₀ arylene group and a C₂-C₄₀ heteroarylene group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, a C₆-C₄₀ arylthio group, —N(Q₁₁)(Q₁₂), and —Si(Q₁₃)(Q₁₄)(Q₁₅); and

Q₁₁ to Q₁₅ may be each independently selected from a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group;

a C₁-C₄₀ alkyl group, a C₂-C₄₀ alkenyl group, a C₂-C₄₀ alkynyl group, and a C₁-C₄₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group.

According to one or more embodiments of the present invention, an organic light-emitting device includes a first electrode; a second electrode facing the first electrode; and an organic layer between the first electrode and the second electrode, wherein the organic layer includes at least one of the condensed cyclic compounds.

### BRIEF DESCRIPTION OF THE DRAWINGS

These and/or other aspects will become apparent and more readily appreciated from the following description of the embodiments, taken in conjunction with the drawings, in which

FIG. 1 is a schematic view of an organic light-emitting device according to an embodiment; and

FIG. 2 is a graph showing current efficiency with respect to luminance of the organic light-emitting devices of Comparative Example 1 and Examples 1 to 3.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the present invention refers to “one or more embodiments of the present invention.”

A condensed cyclic compound according to an embodiment may be represented by Formula 1 illustrated below:

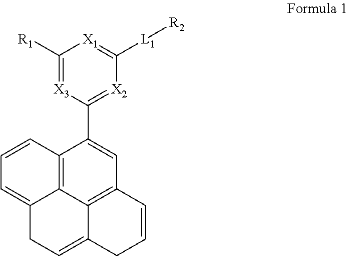

wherein in Formula 1,

X₁, X₂, and X₃ may be each independently N or —CH, and at least one of X₁, X₂, and X₃ may be N.

R₁and R₂ may be each independently selected from a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group;

a C₁-C₄₀ alkyl group, a C₂-C₄₀ alkenyl group, a C₂-C₄₀ alkynyl group, and a C₁-C₄₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group.

L₁ may be selected from a direct bond; a C₆-C₄₀ arylene group; a C₂-C₄₀ heteroarylene group; and a C₆-C₄₀ arylene group and a C₂-C₄₀ heteroarylene group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group, —N(Q₁₁)(Q₁₂), and —Si(Q₁₃)(Q₁₄)(Q₁₅); and

Q₁₁ to Q₁₅ may be each independently selected from a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group;

a C₁-C₄₀ alkyl group, a C₂-C₄₀ alkenyl group, a C₂-C₄₀ alkynyl group, and a C₁-C₄₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ arloxy group, and a C₆-C₄₀ arylthio group.

For example, R₁ and R₂ may be each independently selected from a hydrogen, a deuterium, a phenyl group, a pentalenyl group, and indenyl group, a naphthyl group, an azulenyl group, an indacenyl group, an acenaphthyl group, a biphenyl group, a heptalenyl group, a phenalenyl group, a fluorenyl group, a phenanthrenyl group, an anthyrl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isooxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran group, an indolyl group, an isoindolyl group, an indolizinyl group, a benzofuryl group, an isobenzofuryl group, an indazolyl group, a benzimidazolyl group, a benzoxazolyl group, a benzisooxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a pyridoindolyl group, a dibenzofuryl group, a phenanthridinyl group, a benzoquinolyl group, a phenazinyl group, a dibenzosilolyl group, a dibenzothiophenyl group, and a benzocarbazolyl group; and

a phenyl group, a pentalenyl group, an indenyl group, a naphthyl group, an azulenyl group, an indacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isooxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran group, an indolyl group, an isoindolyl group, an indolizinyl group, a benzofuryl group, an isobenzofuryl group, an indazolyl group, a benzimidazolyl group, a benzoxazolyl group, a benzisooxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a pyridoindolyl group, a dibenzofuryl group, a phenanthridinyl group, a benzoquinolyl group, a phenazinyl group, a dibenzosilolyl group, a dibenzothiophenyl group and a benzocarbazolyl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group.

For example, R₁ and R₂ may each be independently represented by any one of Formulae 2A to 2D below:

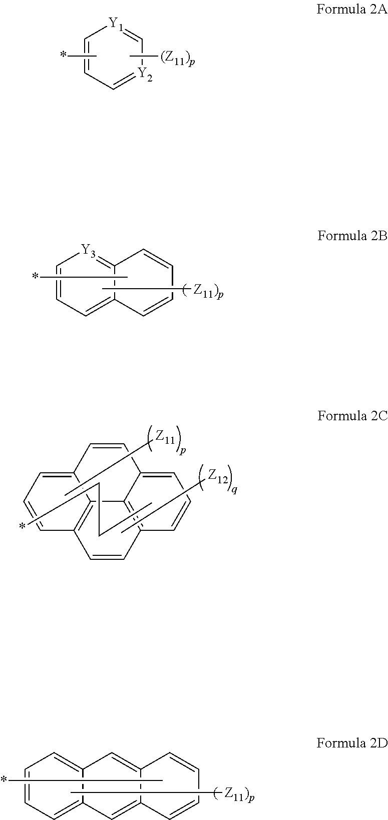

in Formulae 2A to 2D,

Y₁, Y₂, and Y₃ may be each independently N or —CH.

Z₁₁ and Z₁₂ may be each independently selected from a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group;

a C₁-C₂₀ alkyl group and a C₁-C₂₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof; and

a C₆-C₂₀ aryl group and a C₂-C₂₀ heteroaryl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group.

p may be an integer of 3 to 9; q may be 4 or 5; and * may be a binding site. For example, p may be an integer of 3 to 5 in Formula 2A, an integer of 3 to 7 in Formula 2B, an integer of 3 to 5 in Formula 2C, and an integer of 3 to 9 in Formula 2D. For example, p may be 3 in Formula 2A, 6 in Formula 2B, 5 in Formula 2C, and 9 in Formula 2D.

For example, R₁ and R₂ may each be independently represented by any one of Formulae 3A to 3J below:

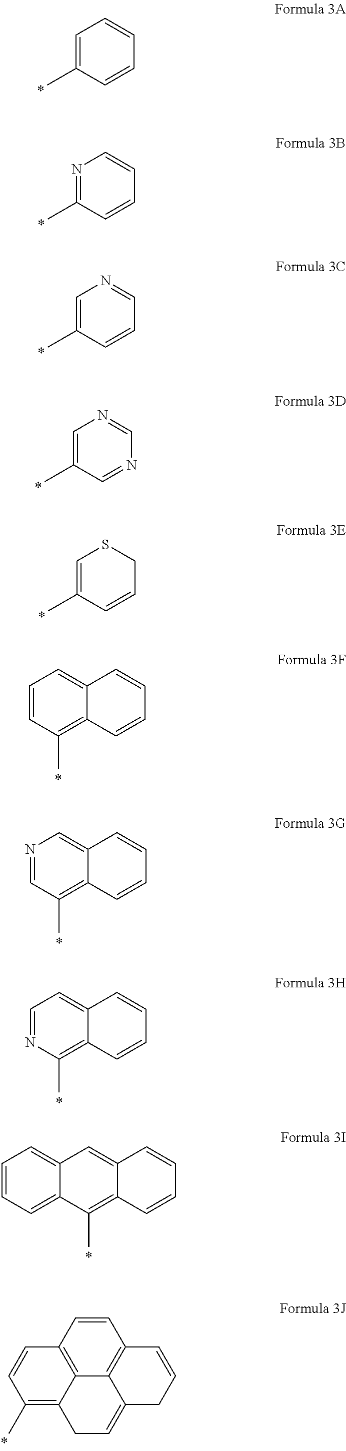

in the formulae above, * indicates a binding site.

L₁ may be selected from a direct bond, a phenylene group, a pentalenylene group, an indenylene group, a naphthylene group, an azulenylene group, an indacenylene group, an acenaphthylene group, a biphenylene group, a heptalenylene group, a phenalenylene group, a fluorenylene group, a phenanthrenylene group, an anthrylene group, a fluoranthenylene group, a pyrenylene group, a benzofluorenylene group, a naphthacenylene group, a chrysenylene group, and a triphenylenylene group; and

a phenylene group, a pentalenylene group, an indenylene group, a naphthylene group, an azulenylene group, an indacenylene group, an acenaphthylene group, a biphenylene group, a heptalenylene group, a phenalenylene group, a fluorenylene group, a phenanthrenylene group, an anthrylene group, a fluoranthenylene group, a pyrenylene group, a benzofluorenylene group, a naphthacenylene group, a chrysenylene group, and a triphenylenylene group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group.

For example, L₁ may be a direct bond, or may be represented by any one of Formulae 4A and 4B illustrated below.

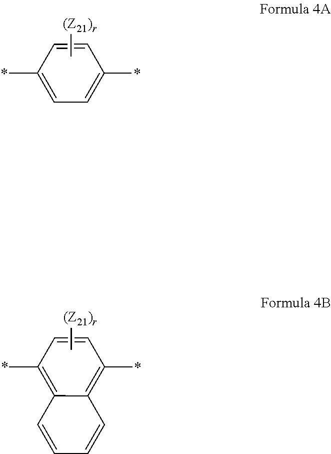

wherein in Formulae 4A and 4B,

Z₂₁ may be each independently selected from a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₂-C₂₀ alkyl group, a C₁-C₂₀ alkoxy group, a C₆-C₂₀ aryl group, and a C₂-C₂₀ heteroaryl group;

a C₁-C₂₀ alkyl group and a C₁-C₂₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof; and

a C₆-C₂₀ aryl group and a C₂-C₂₀ heteroaryl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group.

r may be an integer of 4 to 6, and * indicates a binding site. For example, r may be 4 in Formula 4A, and 6 for Formula 4B.

For example, L₁ may be a direct bond, or may be represented by any one of Formulae 5A and 5B illustrated below.

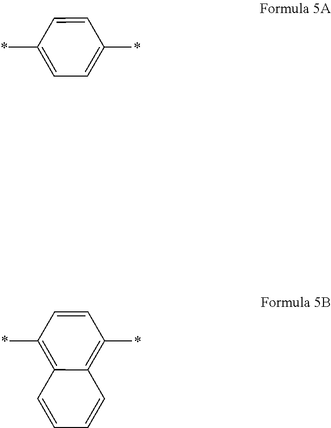 [SMILES: *c1ccc(*)cc1 ; *c1ccc(*)c2ccccc12]

In Formulae 5A and 5B, * indicates a binding site.

The condensed cyclic compound of Formula 1 may be represented by any one of Formulae 1A to 1C below:

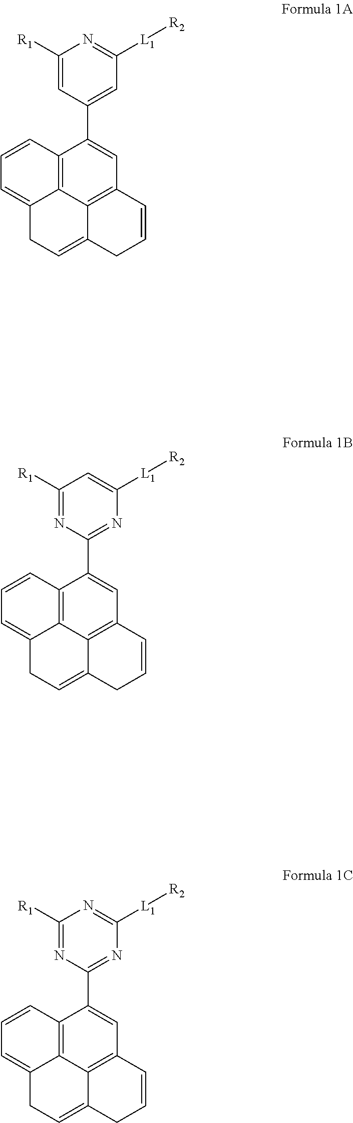

R₁ and R₂ in Formulae 1A to 1C may be each independently selected from a C₆-C₄₀ aryl group and a C₂-C₄₀ heteroaryl group. L₁ may be selected from a direct bond, a C₆-C₄₀ arylene group, and a C₂-C₄₀ heteroarylene group.

R₁ and R₂ in Formulae 1A to 1C may be each independently selected from a phenyl group, a pentalenyl group, an indenyl group, a naphthyl group, an azulenyl group, an indacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isooxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran group, an indolyl group, an isoindolyl group, an indolizinyl group, a benzofuryl group, an isobenzofuryl group, an indazolyl group, a benzimidazolyl group, a benzoxazolyl group, a benzisooxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a pyridoindolyl group, a dibenzofuryl group, a phenanthridinyl group, a benzoquinolyl group, a phenazinyl group, a dibenzosilolyl group, a dibenzothiophenyl group, and a benzocarbazolyl group.

For example, R₁ and R₂ may each be independently represented by any one of Formulae 3A to 3J below:

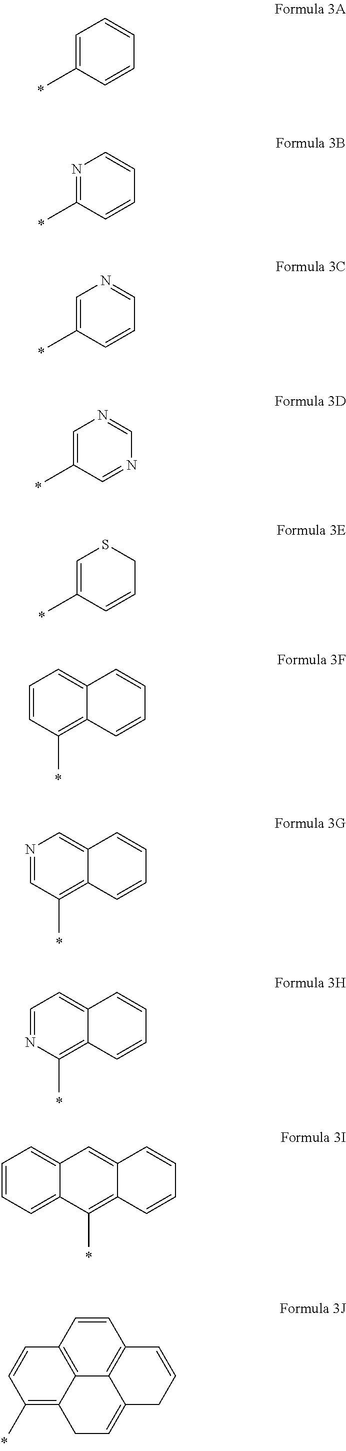

in the formulae above, * indicates a binding site.

For example, R₂ may be represented by any one of Formulae 3A, 3F, 3I, and 3J.

L₁ may be selected from a direct bond, a phenylene group, a pentalenylene group, an indenylene group, a naphthylene group, an azulenylene group, an indacenylene group, an acenaphthylene group, a biphenylene group, a heptalenylene group, a phenalenylene group, a fluorenylene group, a phenanthrenylene group, an anthrylene group, a fluoranthenylene group, a pyrenylene group, a benzofluorenylene group, a naphthacenylene group, a chrysenylene group, and a triphenylenylene group.

For example, L₁ may be a direct bond, or may be represented by any one of Formulae 5A and 5B illustrated below.

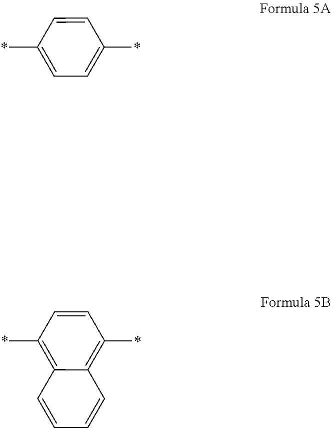 [SMILES: *c1ccc(*)cc1 ; *c1ccc(*)c2ccccc12]

In Formulae 5A and 5B, * indicates a binding site.

The condensed cyclic compound represented by Formula 1 may be one of Compounds 1 to 18 below, but is not limited thereto:

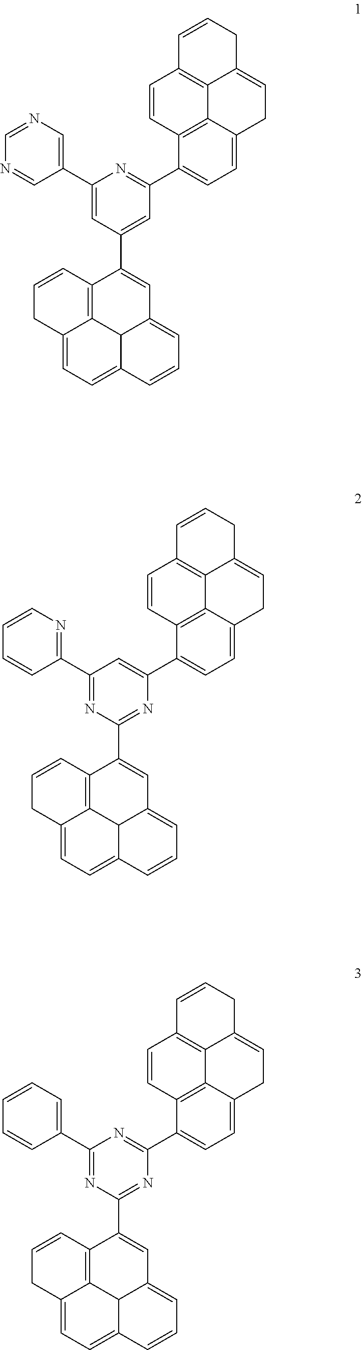 [SMILES: C1=CC2=CC=C3CC=CC4=C3C2C(=C1)C=C4c1cc(-c2cncnc2)nc(-c2ccc3c4c5c(ccc24)C=CCC5=CC3)c1 ; C1=CC2=CC=C3CC=CC4=C3C2C(=C1)C=C4c1nc(-c2ccccn2)cc(-c2ccc3c4c5c(ccc24)C=CCC5=CC3)n1 ; C1=CC2=CC=C3CC=CC4=C3C2C(=C1)C=C4c1nc(-c2ccccc2)nc(-c2ccc3c4c5c(ccc24)C=CCC5=CC3)n1]

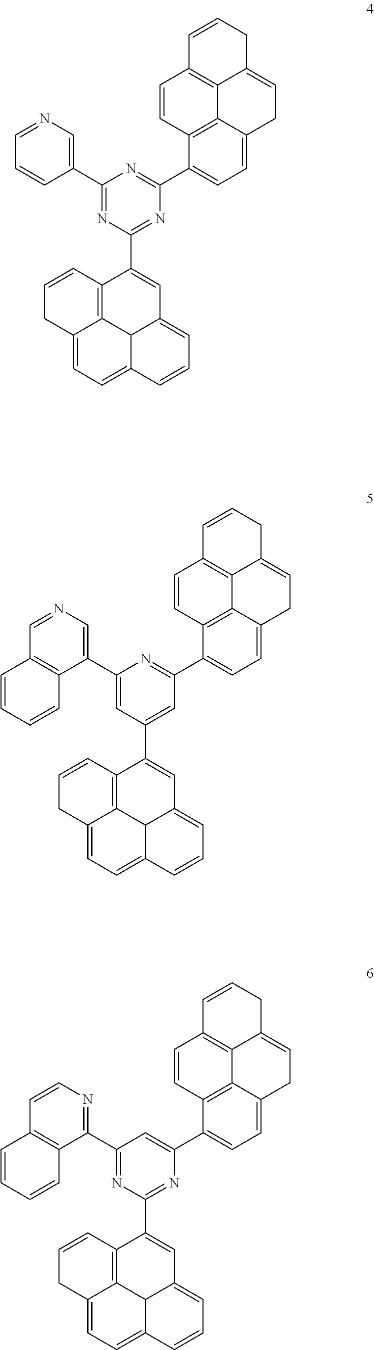 [SMILES: C1=CC2=CC=C3CC=CC4=C3C2C(=C1)C=C4c1nc(-c2cccnc2)nc(-c2ccc3c4c5c(ccc24)C=CCC5=CC3)n1 ; C1=CC2=CC=C3CC=CC4=C3C2C(=C1)C=C4c1cc(-c2cncc3ccccc23)nc(-c2ccc3c4c5c(ccc24)C=CCC5=CC3)c1 ; C1=CC2=CC=C3CC=CC4=C3C2C(=C1)C=C4c1nc(-c2nccc3ccccc23)cc(-c2ccc3c4c5c(ccc24)C=CCC5=CC3)n1]

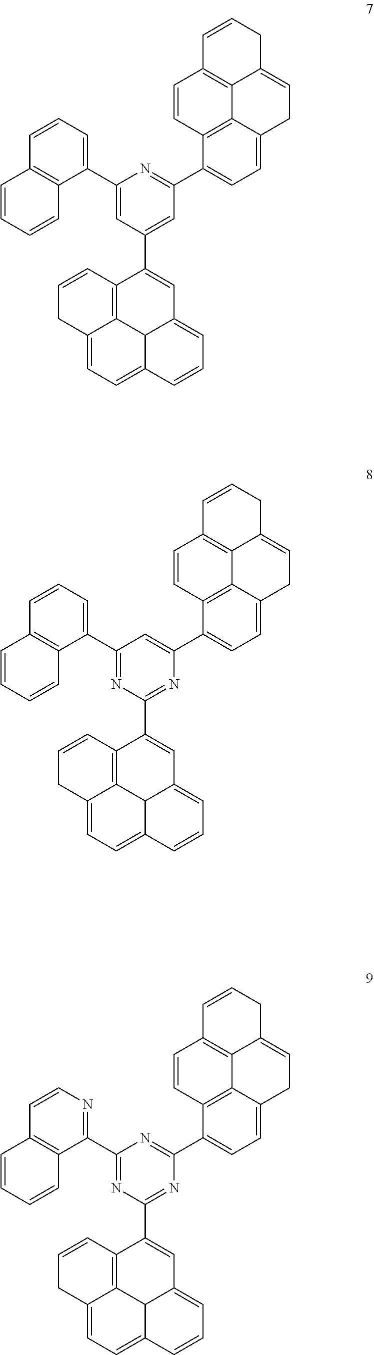 [SMILES: C1=CC2=CC=C3CC=CC4=C3C2C(=C1)C=C4c1cc(-c2cccc3ccccc23)nc(-c2ccc3c4c5c(ccc24)C=CCC5=CC3)c1 ; C1=CC2=CC=C3CC=CC4=C3C2C(=C1)C=C4c1nc(-c2cccc3ccccc23)cc(-c2ccc3c4c5c(ccc24)C=CCC5=CC3)n1 ; C1=CC2=CC=C3CC=CC4=C3C2C(=C1)C=C4c1nc(-c2nccc3ccccc23)nc(-c2ccc3c4c5c(ccc24)C=CCC5=CC3)n1]

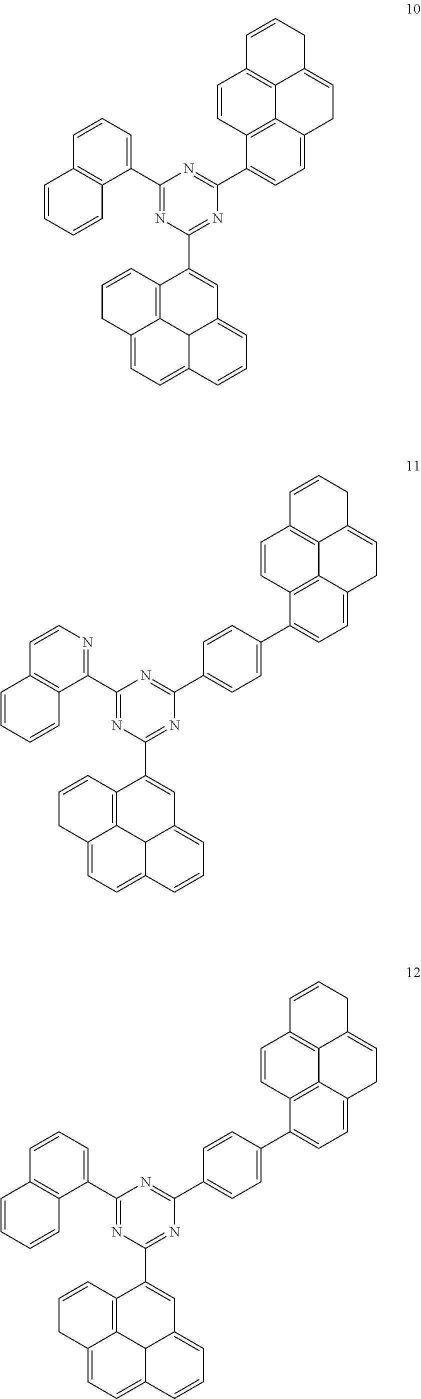 [SMILES: C1=CC2=CC=C3CC=CC4=C3C2C(=C1)C=C4c1nc(-c2cccc3ccccc23)nc(-c2ccc3c4c5c(ccc24)C=CCC5=CC3)n1 ; C1=CC2=CC=C3CC=CC4=C3C2C(=C1)C=C4c1nc(-c2ccc(-c3ccc4c5c6c(ccc35)C=CCC6=CC4)cc2)nc(-c2nccc3ccccc23)n1 ; C1=CC2=CC=C3CC=CC4=C3C2C(=C1)C=C4c1nc(-c2ccc(-c3ccc4c5c6c(ccc35)C=CCC6=CC4)cc2)nc(-c2cccc3ccccc23)n1]

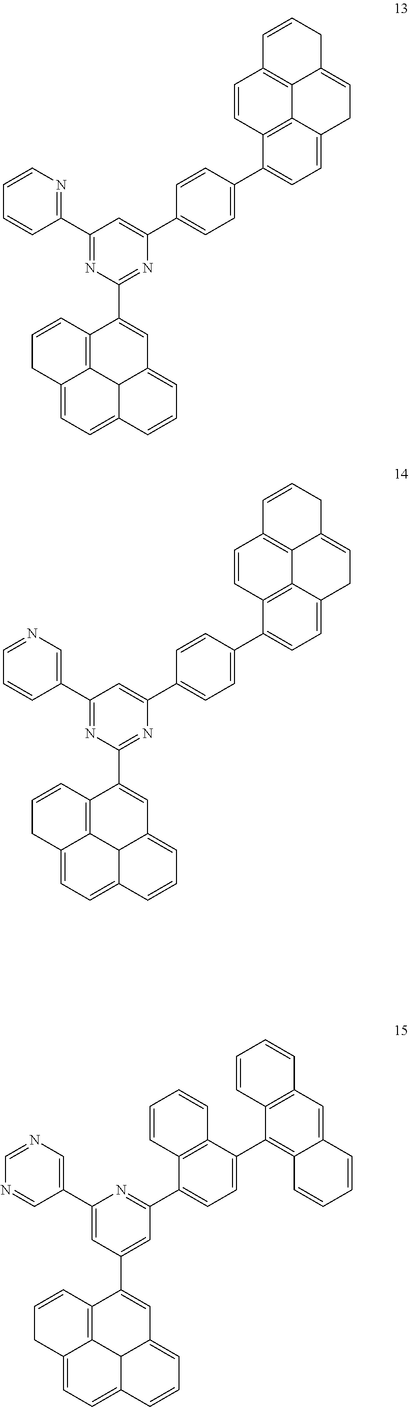 [SMILES: C1=CC2=CC=C3CC=CC4=C3C2C(=C1)C=C4c1nc(-c2ccc(-c3ccc4c5c6c(ccc35)C=CCC6=CC4)cc2)cc(-c2ccccn2)n1 ; C1=CC2=CC=C3CC=CC4=C3C2C(=C1)C=C4c1nc(-c2ccc(-c3ccc4c5c6c(ccc35)C=CCC6=CC4)cc2)cc(-c2cccnc2)n1 ; C1=CC2=CC=C3CC=CC4=C3C2C(=C1)C=C4c1cc(-c2cncnc2)nc(-c2ccc(-c3c4ccccc4cc4ccccc34)c3ccccc23)c1]

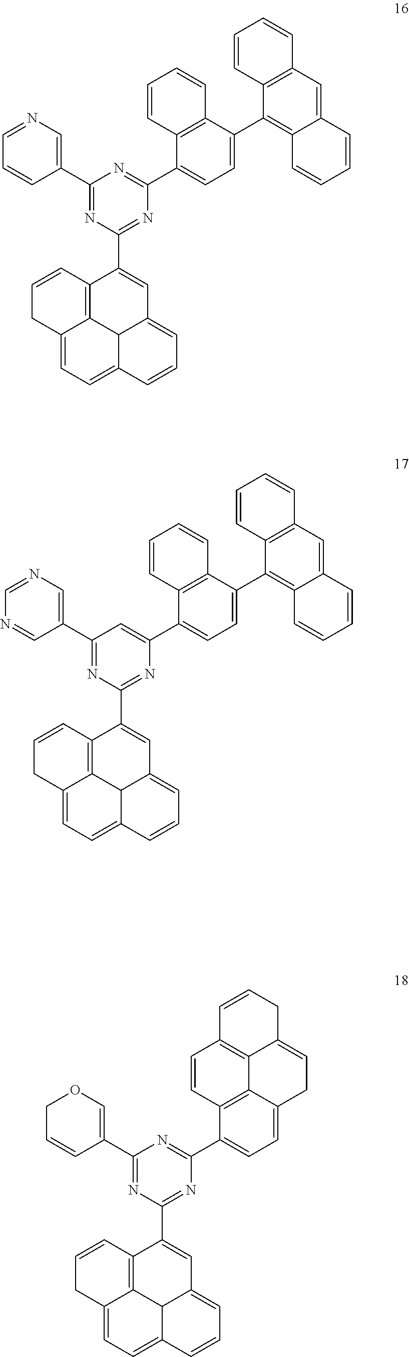 [SMILES: C1=CC2=CC=C3CC=CC4=C3C2C(=C1)C=C4c1nc(-c2cccnc2)nc(-c2ccc(-c3c4ccccc4cc4ccccc34)c3ccccc23)n1 ; C1=CC2=CC=C3CC=CC4=C3C2C(=C1)C=C4c1nc(-c2cncnc2)cc(-c2ccc(-c3c4ccccc4cc4ccccc34)c3ccccc23)n1 ; C1=CC2=CC=C3CC=CC4=C3C2C(=C1)C=C4c1nc(C2=COCC=C2)nc(-c2ccc3c4c5c(ccc24)C=CCC5=CC3)n1]

The condensed cyclic compound of Formula 1 may be used (utilized) as a material for an electron transport region of an organic light-emitting device.

The condensed cyclic compound of Formula 1 has excellent energy band matching characteristics with respect to an emission layer; and allows electrons to be easily supplied, thereby improving the color change in a relatively low-gradation region.

The unsubstituted C₁-C₄₀ alkyl group (or C₁-C₄₀ alkyl group) used herein may be a linear or branched C₁-C₄₀ alkyl group, and examples thereof are a methyl group, an ethyl group, a propyl group, an isobutyl group, a sec-butyl group, a pentyl group, an iso-amyl group, and a hexyl group.

The unsubstituted C₁-C₄₀ alkoxy group (or C₁-C₄₀ alkoxy group) used herein may be represented by —OA (A is an unsubstituted C₁-C₄₀ alkyl group described above), and examples thereof are a methoxy group, an ethoxy group, and an isopropyloxy group.

The unsubstituted C₂-C₄₀ alkenyl group (or C₂-C₄₀ alkenyl group) used herein refers to an unsubstituted C₂-C₄₀ alkyl group that has at least one carbon double bond in the middle or end thereof, and examples thereof are an ethenyl group, a propenyl group, and a butenyl group.

The unsubstituted C₂-C₄₀ alkynyl group (or C₂-C₄₀ alkynyl group) used herein refers to an unsubstituted C₂-C₆₀ alkyl group that has at least one carbon triple bond in the middle or end thereof, and examples thereof are an ethynyl group and a propynyl group.

The C₆-C₄₀ aryl group is a monovalent group having a carbocyclic aromatic system having 6 to 40 carbon atoms including at least one aromatic ring. The C₆-C₄₀ arylene group is a divalent group having a carbocyclic aromatic system having 6 to 40 carbon atoms including at least one aromatic ring. When the aryl group and the arylene group have at least two rings, they may be fused to each other.

Examples of the C₆-C₄₀ aryl group are a phenyl group, a C₁-C₁₀ alkylphenyl group (for example, an ethylphenyl group), a C₁-C₁₀ alkylbiphenyl group (for example, an ethylbiphenyl group), a halophenyl group (for example, an o-, m- or p-fluorophenyl group, or a dichlorophenyl group), a dicyanophenyl group, a trifluoromethoxyphenyl group, an o-, m-, or p-tollyl group, an o-, m-, or p-cumenyl group, a mesityl group, a phenoxyphenyl group, a (α,α-dimethylbenzene)phenyl group, a (N,N′-dimethyl)aminophenyl group, a (N,N′-a diphenyl)aminophenyl group, a pentalenyl group, an indenyl group, a naphthyl group, a halonaphthyl group (for example, a fluoronaphthyl group), a C₁-C₁₀ alkylnaphthyl group (for example, a methylnaphthyl group), a C₁-C₁₀ alkoxynaphthyl group (for example, a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylenyl group, a pyrenyl group, a chrysenyl group, an ethylchrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coroneryl group, a trinaphthylenyl group, a heptaphenyl group, a heptacenyl group, a pyranthrenyl group, and an ovalenyl group.

The C₂-C₄₀ heteroaryl group used herein refers to a monovalent group having one or more aromatic rings that have at least one hetero atom selected from nitrogen (N), oxygen (O), phosphorous (P), silicon (Si), and sulfur (S) (as a ring-forming atom), and carbon atoms as the remaining ring atoms. The C₂-C₄₀ heteroarylene group used herein refers to a divalent group having one or more aromatic rings that have at least one hetero atom selected from nitrogen (N), oxygen (O), phosphorous (P), silicon (Si), and sulfur (S) (as a ring-forming atom), and carbon atoms as the remaining ring atoms. In this regard, when the heteroaryl group and the heteroarylene group each include two or more rings, the rings may be fused to each other.

Examples of the C₂-C₄₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoan imidazolyl group, an imidazo pyridinyl group, and an imidazo pyrimidinyl group.

The C₆-C₄₀ aryloxy group may be represented by —OA₂ (wherein A₂ indicates the substituted or unsubstituted C₆-C₄₀ aryl group), and the C₆-C₄₀ arylthio group may be represented by —SA₃ (wherein A₃ indicates a substituted or unsubstituted C₆-C₄₀ aryl group).

The condensed cyclic compound represented by Formula 1 may be synthesized by using (utilizing) a known (or suitable) organic synthesis method. The synthesis method for the condensed cyclic compound may be obvious to one of ordinary skill in the art by referring to the Examples to be explained hereinafter.

The condensed cyclic compound of Formula 1 may be used (utilized) in an organic layer between a pair of electrodes of an organic light-emitting device. For example, the condensed cyclic compound may be used (utilized) in an electron transport region disposed between a cathode and an emission layer.

Accordingly, an organic light-emitting device may include a first electrode; a second electrode facing the first electrode, and an organic layer disposed between the first electrode and the second electrode, wherein the organic layer includes at least one of the condensed cyclic compound of Formula 1 described above.

The “organic layer” used herein refers to a layer that includes an organic compound and that is constituted of one or more layers. For example, the organic layer may include an emission layer, a hole transport region, and an electron transport region.

The hole transport region may include at least one of a hole injection layer, a hole transport layer, and an electron blocking layer.

The electron transport region may include at least one of an electron injection layer, an electron transport layer, and a hole blocking layer. The electron transport region may further include a buffer layer located near the emission layer.

An organic layer may not be formed of only an organic compound, and may further include an inorganic compound or an inorganic material. For example, the organic layer may include, in the same single layer, in addition to an organic compound, an inorganic compound or an inorganic material, for example, an organometallic complex. In some embodiments, an organic layer may include, in addition to a layer that includes only an organic compound, a layer that includes only an inorganic compound or an inorganic material.

In the organic layer, the buffer layer of the electron transport region may further include at least one of the condensed cyclic compound of Formula 1.

The emission layer may further include an anthracene compound, an arylamine compound, or a styryl compound.

The electron transport layer may include an electron transport organic compound and a metal-containing material. The metal-containing material may include a Li complex.

The hole transport region may include a charge-generation layer. The charge-generation material (for the charge-generation layer) may be, for example, a p-dopant.

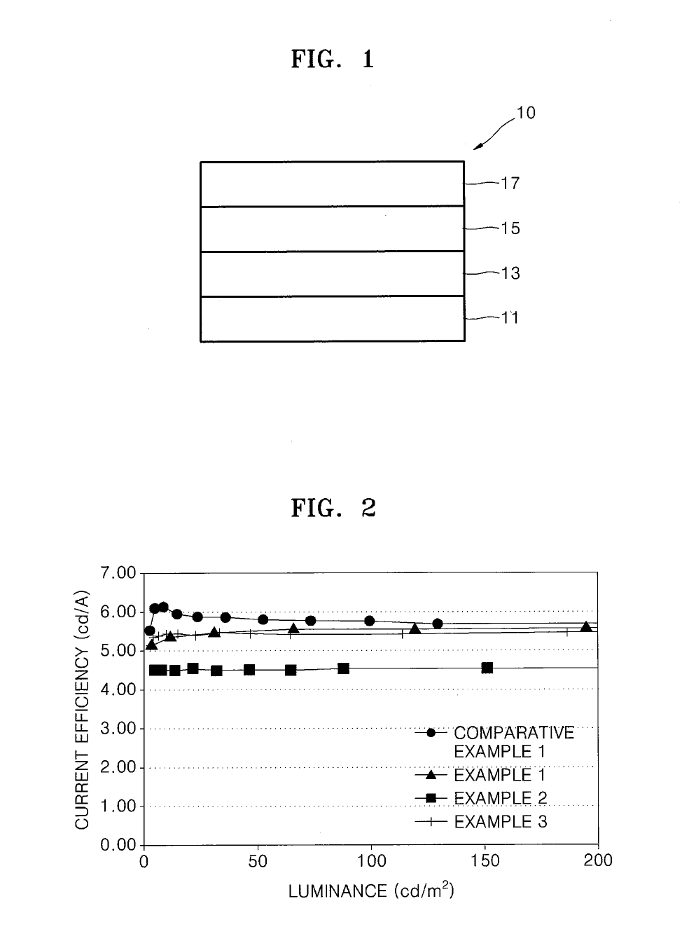

FIG. 1 is a schematic view of an organic light-emitting device 10 according to an embodiment. Hereinafter, the structure of an organic light-emitting device according to an embodiment, and a method of manufacturing an organic light-emitting device according to an embodiment will be described in connection with FIG. 1.

The organic light-emitting device 10 includes a substrate 11, a first electrode 13, an organic layer 15, and a second electrode 17, which are sequentially stacked.

For use (usage) as the substrate 11, any suitable substrate that is used (utilized) in general organic light-emitting devices may be used (utilized), and the substrate 11 may be a glass substrate or transparent plastic substrate, each with excellent mechanical strength, thermal stability, transparency, surface smoothness, ease of handling, and water repellency.

The first electrode 13 may be formed by, for example, depositing or sputtering a material for a first electrode on the substrate 11. When the first electrode 13 is an anode, the material for the first electrode may be selected from materials with a high work function to make holes easily injected. The first electrode 13 may be a reflective electrode or a transmissive electrode. The material for the first electrode 13 may be a transparent and highly conductive material, and examples of such a material are indium tin oxide (ITO), indium zinc oxide (IZO), tin oxide (SnO₂), and zinc oxide (ZnO). According to another embodiment, magnesium (Mg), silver (Ag), aluminum (Al), aluminum:lithium (Al:Li), calcium (Ca), silver:indium tin oxide (Ag:ITO), magnesium:indium (Mg:In), or magnesium:silver (Mg:Ag) may be used (utilized) to form a reflective electrode for use (usage) as the first electrode 13. The first electrode 13 may have a single-layer structure, or a multi-layer structure including two or more layers. For example, the first electrode 13 may have a three-layered structure of ITO/Ag/ITO, but the structure of the first electrode 110 is not limited thereto.

The organic layer 15 is disposed on the first electrode 13.

The organic layer 15 may include a hole transport region, an emission layer, and an electron transport region.

The hole transport region may include at least one of a hole injection layer, a hole transport layer, and an electron blocking layer. The electron transport region may include at least one of an electron injection layer, an electron transport layer, and a hole blocking layer. The electron transport region may further include a buffer layer located near the emission layer.

A hole injection layer (HIL) may be formed on the first electrode 13 by using (utilizing) various suitable methods, such as vacuum deposition, spin coating, casting, langmuir-blodgett (LB) deposition, or the like.

When a hole injection layer is formed by vacuum deposition, the deposition conditions may vary according to a material that is used (utilized) to form the hole injection layer, and the structure and thermal characteristics of the hole injection layer. For example, the deposition conditions may include a deposition temperature of about 100 to about 500° C., a vacuum pressure of about 10⁻⁸ to about 10⁻³ torr, and a deposition rate of about 0.01 to about 100 Å/sec. However, the deposition conditions are not limited thereto.

When the hole injection layer is formed using (utilizing) spin coating, coating conditions may vary according to the material used (utilized) to form the hole injection layer, and the structure and thermal properties of the hole injection layer. For example, a coating speed may be from about 2000 rpm to about 5000 rpm, and a temperature at which a heat treatment is performed to remove the solvent after coating may be from about 80° C. to about 200° C. However, the coating conditions are not limited thereto.

A material for the hole injection layer may be, for example, a known (or suitable) hole injection material. Examples of the known (or suitable) hole injection material are N,N′-diphenyl-N,N′-bis-[4-(phenyl-m-tolyl-amino)-phenyl]-biphenyl-4,4′-diamine (DNTPD), a phthalocyanin compound (such as copper phthalocyanine), 4,4′,4″-tris(3-methylphenylphenylamino) triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2T-NATA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), and polyaniline/poly(4-styrenesulfonate) (PANI/PSS), but are not limited thereto.

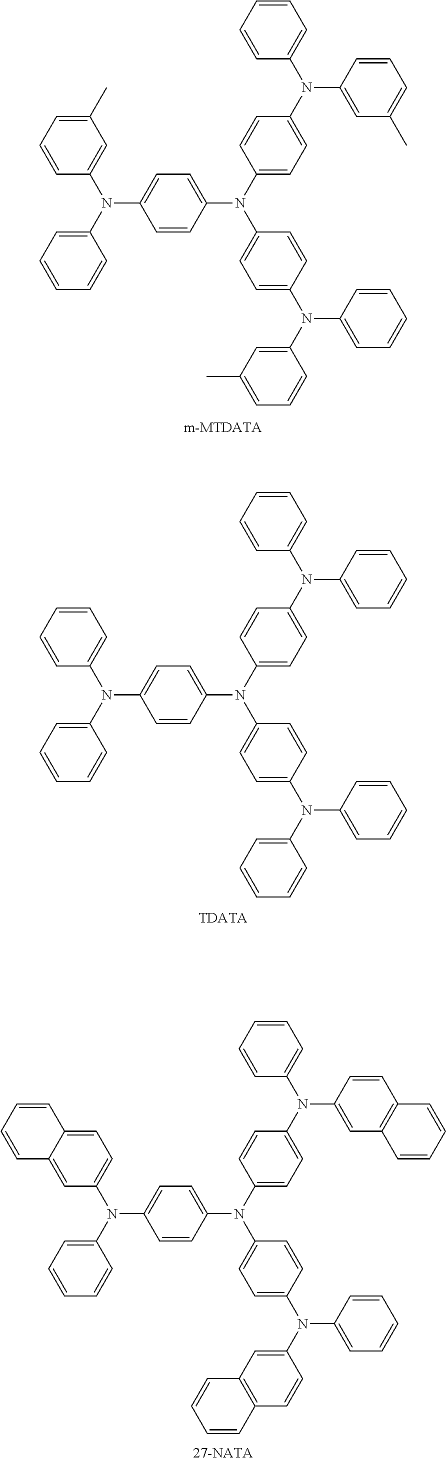

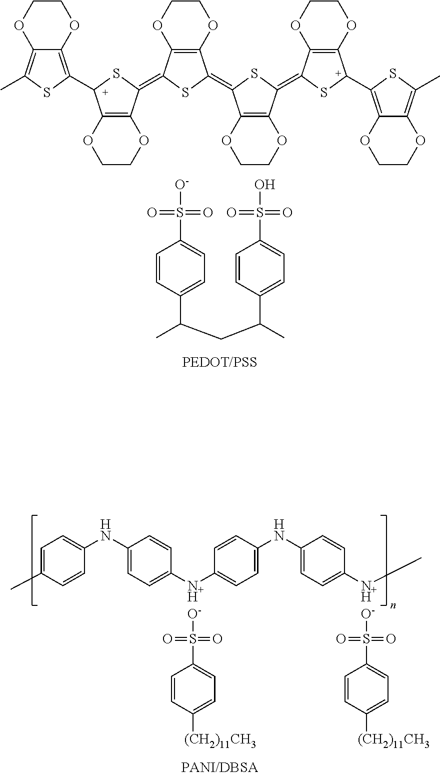

A thickness of the hole injection layer may be in a range of about 100 Å to about 10,000 Å, for example, about 100 Å to about 1,000 Å. In one embodiment, when the thickness of the hole injection layer is within the range described above, the hole injection layer has satisfactory hole injection characteristics without a substantial increase in a driving voltage.

Then, a hole transport layer (HTL) may be formed on the hole injection layer by using (utilizing) vacuum deposition, spin coating, casting, or LB. When the hole transport layer is formed by vacuum deposition or spin coating, the deposition or coating conditions may be similar to those applied to form the hole injection layer although the deposition or coating conditions may vary according to the material that is used (utilized) to form the hole transport layer.

A material for the hole transport layer may be, for example, a known (or suitable) hole transport material. Examples of the known (or suitable) hole transport material are a carbazole derivative, such as N-phenylcarbazole or polyvinylcarbazole, a triphenylamine-based material, such as N,N′-bis(3-methylphenyl)-N,N′-diphenyl-[1,1-biphenyl]-4,4′-diamine (TPD), N,N′-bis(naphthalen-2-yl)-N,N′-bis(phenyl)-benzidine (NPB), N,N′-bis(naphthalen-1-yl)-N,N′-bis(phenyl)-2,2′-dimethylbenzidine (α-NPD), and 4,4′,4″-tris(N-carbazolyl)triphenylamine (TCTA), but are not limited thereto.

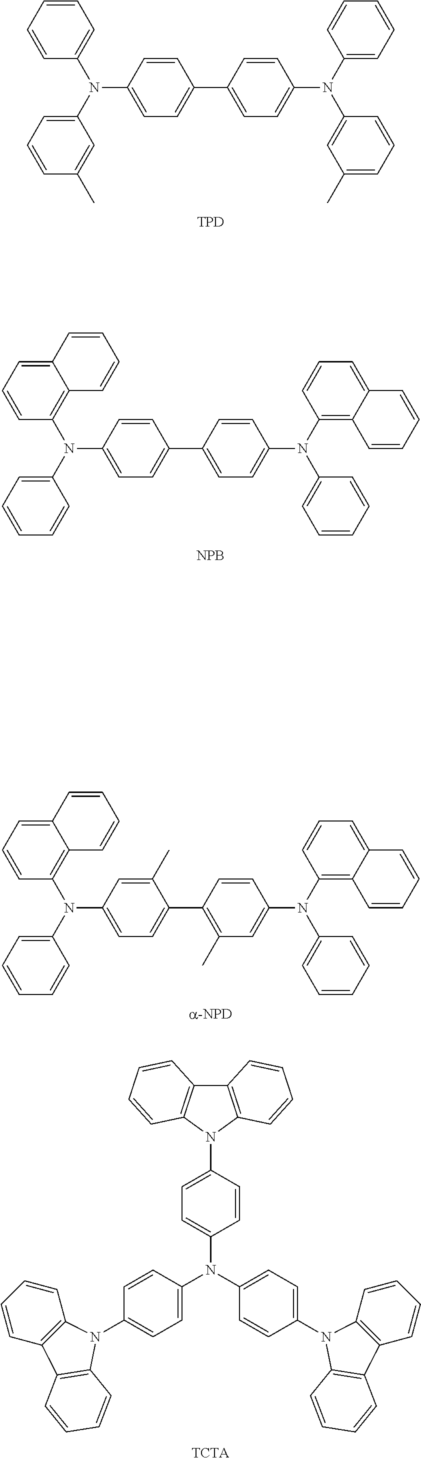 [SMILES: Cc1cccc(N(c2ccccc2)c2ccc(-c3ccc(N(c4ccccc4)c4cccc(C)c4)cc3)cc2)c1 ; "TPD" ; c1ccc(N(c2ccc(-c3ccc(N(c4ccccc4)c4cccc5ccccc45)cc3)cc2)c2cccc3ccccc23)cc1 ; "NPB" ; Cc1cc(N(c2ccccc2)c2cccc3ccccc23)ccc1-c1ccc(N(c2ccccc2)c2cccc3ccccc23)cc1C ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

A thickness of the hole transport layer may be in a range of about 50 Å to about 1,000 Å, for example, about 100 Å to about 800 Å. In one embodiment, when the thickness of the hole transport layer is within these ranges, satisfactory hole transport characteristics are obtained without a substantial increase in driving voltage.

In some embodiments, instead of the hole injection layer and the hole transport layer, a hole injection and transport layer may be formed. The hole injection and transport layer may include at least one material selected from the materials for the hole injection layer and at least one material selected from the materials for the hole transport layer, and may have a thickness of about 500 Å to about 10,000 Å, and for example, about 100 Å to about 1,000 Å. In one embodiment, when the thickness of the hole injection and transport layer is within these ranges, satisfactory hole injection and transport characteristics are obtained without a substantial increase in driving voltage.

In addition, at least one layer of the hole injection layer, the hole transport layer, and the hole injection and transport layer may include at least one of a compound represented by Formula 100 below and a compound represented by Formula 101 below:

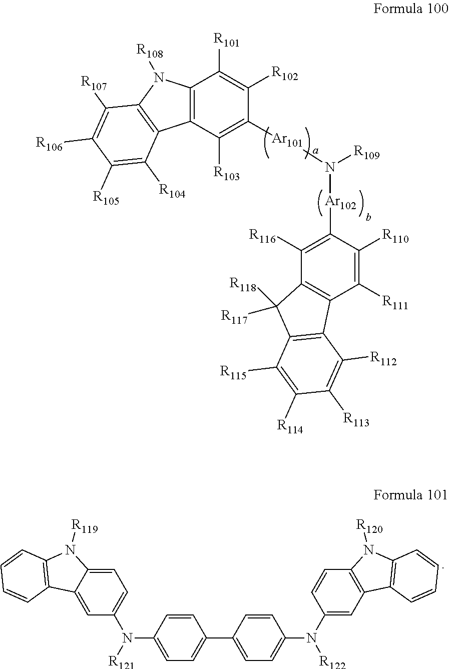

Ar₁₀₁ and Ar₁₀₂ in Formula 100 may be each independently selected from a substituted or unsubstituted C₆-C₄₀ arylene group. For example, Ar₁₀₁ and Ar₁₀₂ may be each independently selected from:

a phenylene group, a pentalenylene group, an indenylene group, a naphthylene group, an azulenylene group, a heptalenylene group, a substituted or unsubstituted acenaphthylene group, a fluorenylene group, a phenalenylene group, a phenanthrenylene group, an anthrylene group, a fluoranthenylene group, a triphenylenylene group, a pyrenylene group, a chrysenylenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthrylene group, a fluoranthenylene group, a triphenylenylene group, a pyrenylene group, a chrysenylenylene group, a naphthacenylene group, a picenylene group, a perylenylene group, and a pentacenylene group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₄₀ aryl group, a C₆-C₄₀ aryloxy group, a C₆-C₄₀ arylthio group, and a C₂-C₄₀ heteroaryl group.

a and b in Formula 100 may be each independently an integer of 0 to 5, or 0, 1, or 2. For example, a may be 1 and b may be 0, but a and b are not limited thereto.

R₁₀₁ to R₁₂₂ in Formulae 100 and 101 may be each independently a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₄₀ alkyl group, a substituted or unsubstituted C₂-C₄₀ alkenyl group, a substituted or unsubstituted C₂-C₄₀ alkynyl group, a substituted or unsubstituted C₁-C₄₀ alkoxy group, a substituted or unsubstituted C₃-C₄₀ cycloalkyl group, a substituted or unsubstituted C₆-C₄₀ aryl group, a substituted or unsubstituted C₆-C₄₀ aryloxy group, or a substituted or unsubstituted C₆-C₄₀ arylthio group.

For example, R₁₀₁ to R₁₀₈ and R₁₁₀ to R₁₂₂ may be each independently selected from: a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, or a hexyl group), a C₁-C₁₀ alkoxy group (for example, a methoxy group, an ethoxy group, a propoxy group, a butoxy group, or a pentoxy group), a phenyl group, a naphthyl group, an anthryl group, a fluorenyl group, and a pyrenyl group;

a C₁-C₁₀ alkyl group, a C₁-C₁₀ alkoxy group, a phenyl group, a naphthyl group, an anthryl group, a fluorenyl group, and a pyrenyl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof, but is not limited thereto.

R₁₀₉ in Formula 100 may be one selected from:

a phenyl group; a naphthyl group; an anthryl group; a biphenyl group; a pyridyl group; and

a phenyl group, a naphthyl group, an anthryl group, a biphenyl group and a pyridyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to an embodiment, the compound represented by Formula 100 may be represented by Formula 100A below, but is not limited thereto:

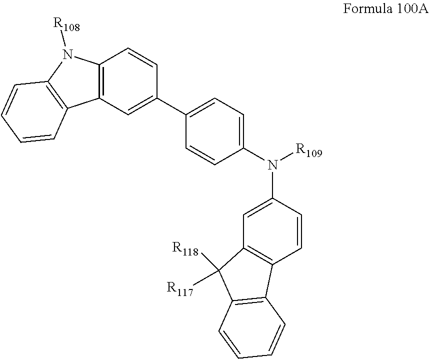

Detailed description about R₁₀₈, R₁₀₉, R₁₁₇, and R₁₁₈ in Formula 100A are already provided above.

For example, at least one layer of the hole injection layer, the hole transport layer, and the hole injection and transport layer may include at least one of Compounds 102 to 121 below, but these layers are not limited thereto and may instead include other materials.

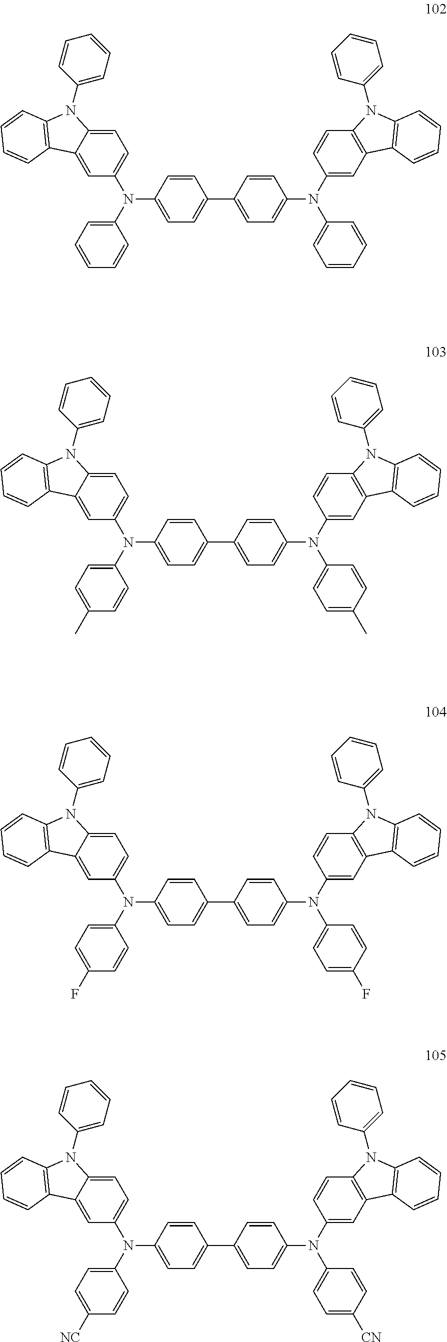 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

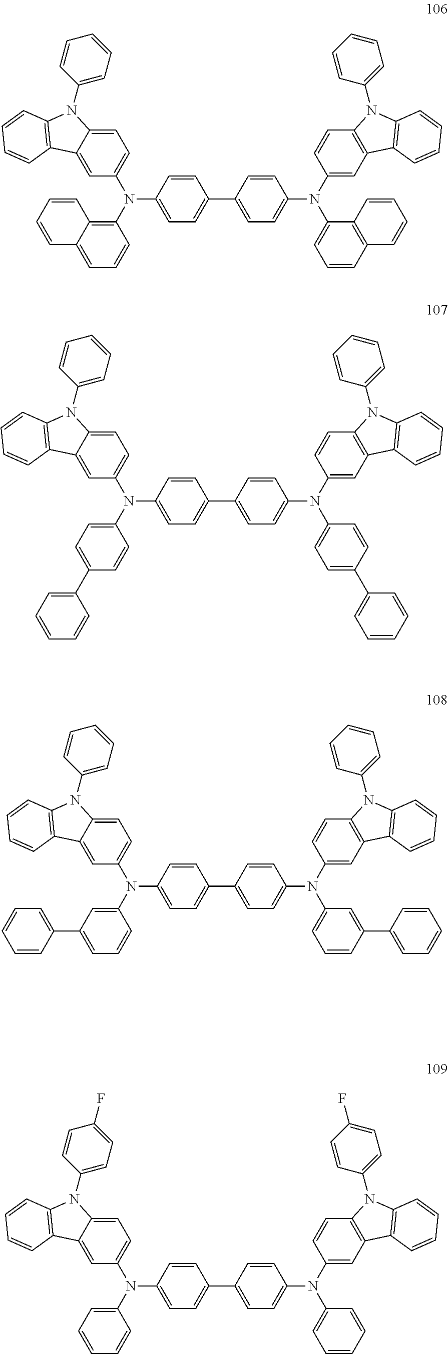 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

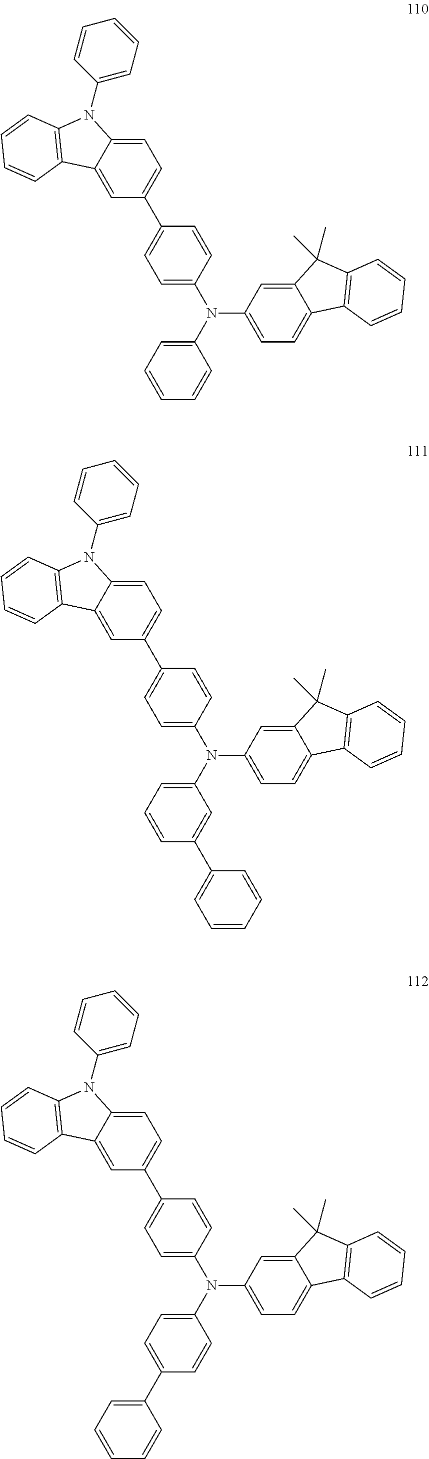 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

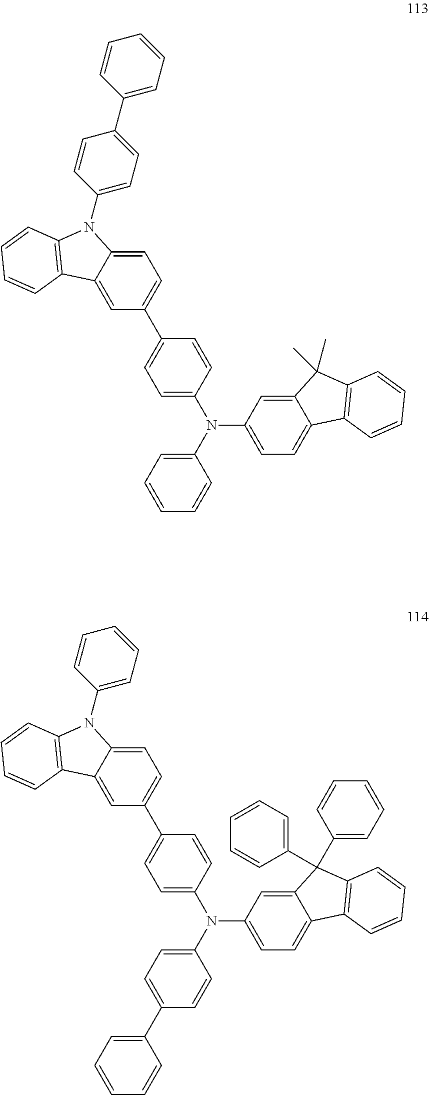 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

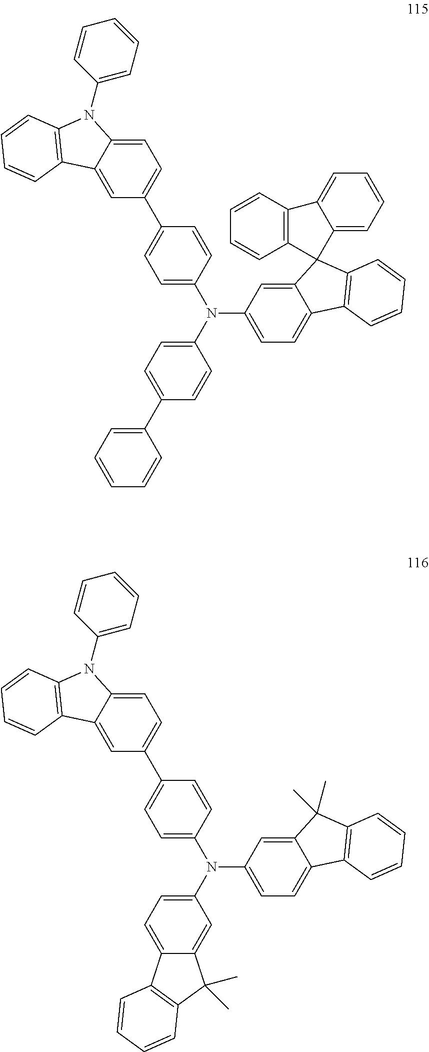 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

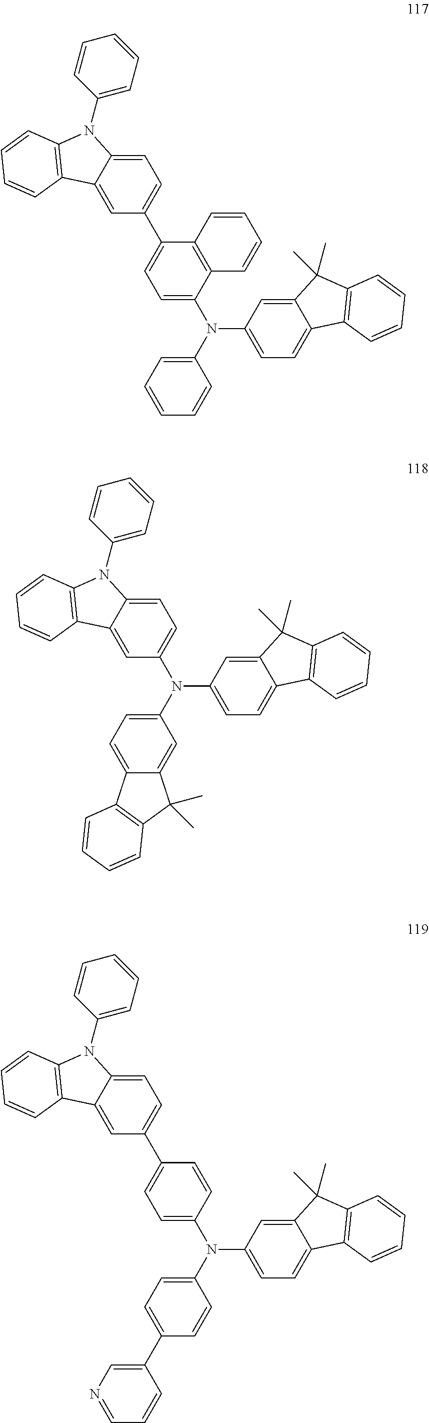 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

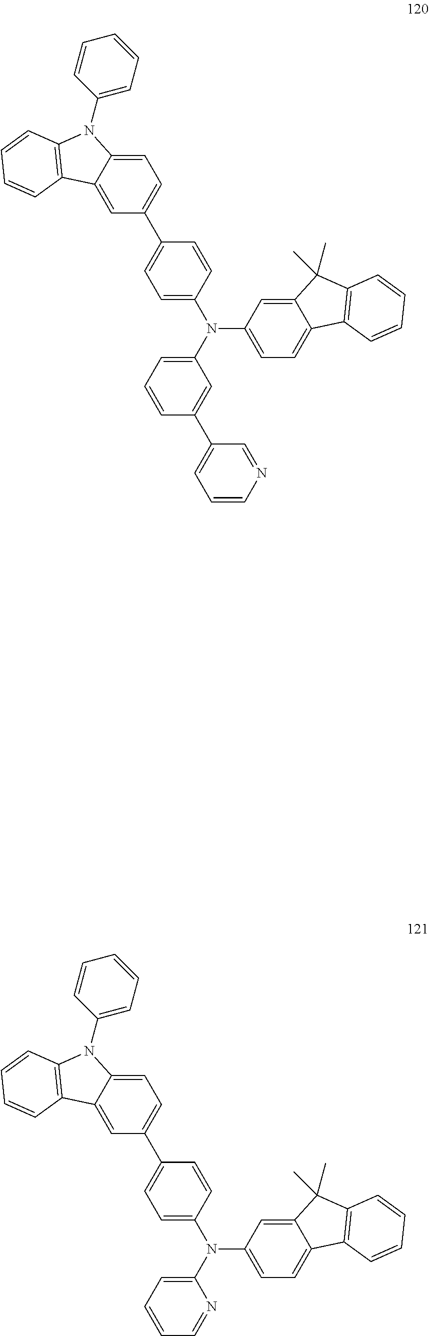 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the hole injection layer, the hole transport layer, and the hole injection and transport layer may further include a charge-generation material to increase the conductivity of the layer, in addition to such known (or suitable) hole injection materials, known (or suitable) hole transport materials, and/or known (or suitable) materials having both hole injection and hole transport capabilities.

The charge-generation material may be, for example, a p-dopant. Non-limiting examples of the p-dopant are a quinone derivative (such as tetracyanoquinonedimethane (TCNQ) or 2,3,5,6-tetrafluoro-tetracyano-1,4-benzoquinonedimethane (F4TCNQ)); a metal oxide (such as tungsten oxide or molybdenium oxide); and a cyano group-containing compound (such as Compound 200 below).

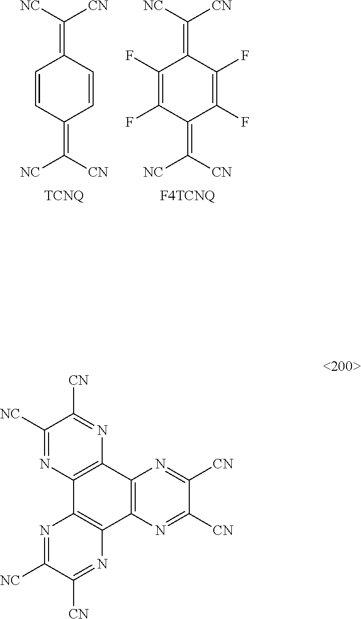

When the hole injection layer, the hole transport layer, and/or the hole injection and transport layer further include the charge-generation material, the charge-generation material may be homogeneously or inhomogeneously dispersed in the layers.

A resonance control layer may be disposed between an emission layer and at least one of the hole injection layer, the hole transport layer, and the hole injection and transport layer. Also, the resonance control layer may compensate for an optical resonance distance according to a wavelength of light emitted from the emission layer, and thus, efficiency of a formed organic light-emitting device may be improved. The resonance control layer may include a known (or suitable) hole injection material and a known (or suitable) hole transport material. Also, the resonance control layer may include a material that is identical to one of the materials included in the hole injection layer, the hole transport layer, and the hole injection and transport layer formed under the resonance control layer.

Subsequently, an emission layer (EML) may be formed on the hole transport layer, the hole injection and transport layer, or the resonance control layer by spin coating, casting, or an LB method. When the emission layer is formed by vacuum deposition or spin coating, the deposition and coating conditions may be similar to those for the formation of the hole injection layer, though the conditions for deposition and coating may vary according to the material that is used (utilized) to form the emission layer.

As a material for forming the emission layer, at least one material selected from any known (or suitable) emission materials (including a host and a dopant) may be used (utilized).

Examlpes of a known (or suitable) host are tris(8-quinolinorate)aluminum (Alq₃), 4,4′-N,N′-dicabazole-biphenyl (CBP), poly(n-vinylcabazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di(naphth-2-yl) anthracene (TBADN), distyrylarylene (DSA), E3, dmCBP (illustrated below), and Compounds 301 to 309 illustrated below, but are not limited thereto.

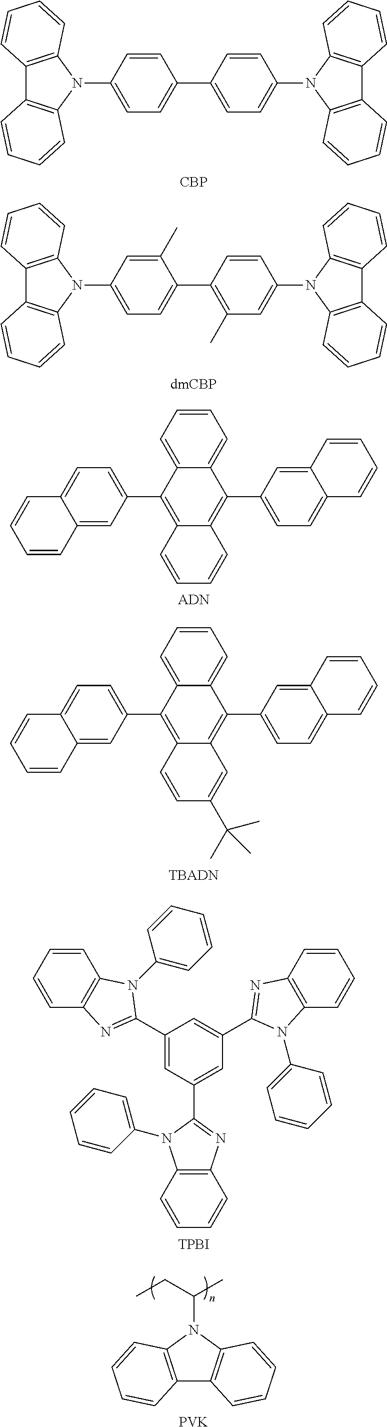

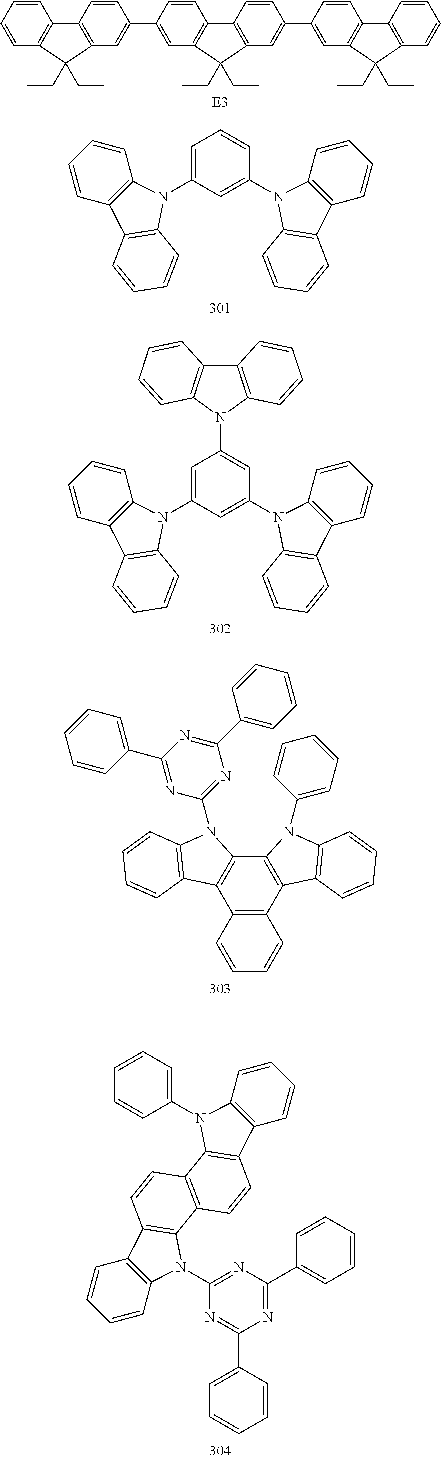

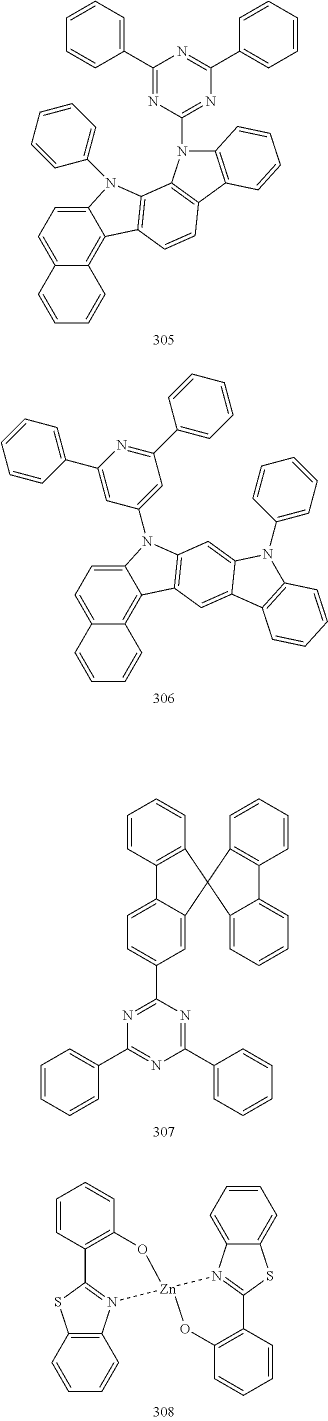

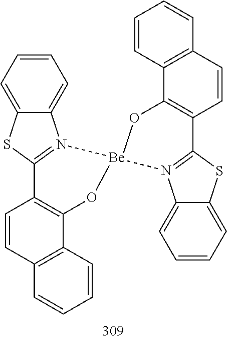

An example of the the host may be an anthracene-based compound represented by Formula 400 below:

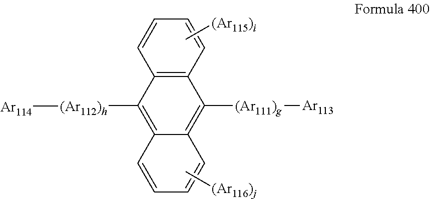

wherein, in Formula 400, Ar₁₁₁ and Ar₁₁₂ may be each independently a substituted or unsubstituted C₆-C₆₀ arylene group; Ar₁₁₃ to Ar₁₁₆ may be each independently a substituted or unsubstituted C₁-C₁₀ alkyl group, or a substituted or unsubstituted C₆-C₆₀ aryl group; and g, h, I, and j are each independently an integer of 0 to 4.

For example, Ar₁₁₁ and Ar₁₁₂ in Formula 400 may be each independently a phenylene group, a naphthylene group, a phenanthrenylene group, or a pyrenylene group; or a phenylene group, a naphthylene group, a phenanthrenylene group, a fluorenyl group, or a pyrenylene group, each substituted with at least one of a phenyl group, a naphthyl group, and an anthryl group, but are not limited thereto.

g, h, i, and j in Formula 400 may each be independently 0, 1, or 2.

Ar₁₁₃ to Ar₁₁₆ in Formula 400 may be each independently selected from a C₁-C₁₀ alkyl group substituted with at least one of a phenyl group, a naphthyl group, and an anthryl group; a phenyl group; a naphthyl group; an anthryl group; a pyrenyl group; a phenanthrenyl group; a fluorenyl group; and a phenyl group, a naphthyl group, an anthryl group, a pyrenyl group, a phenanthrenyl group, and a fluorenyl group, each substituted with at least one of a deuterium, a halogen atom, a hydroxyl group, a cyano group, a nitro group, an amino group, an amidino group, a hydrazine, a hydrazone, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, a fluorenyl group, and

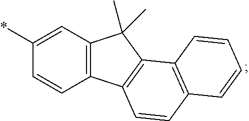 [SMILES: *c1ccc2c(c1)C(C)(C)c1c-2ccc2ccccc12]

but are not limited thereto.

For example, the anthracene-based compound represented by Formula 400 may be one of the following compounds, but is not limited thereto:

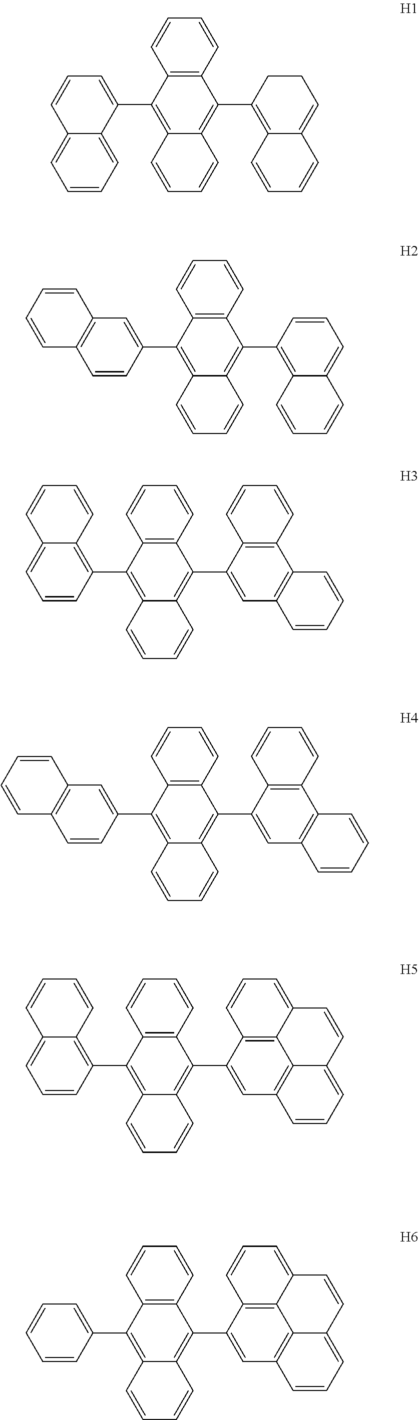

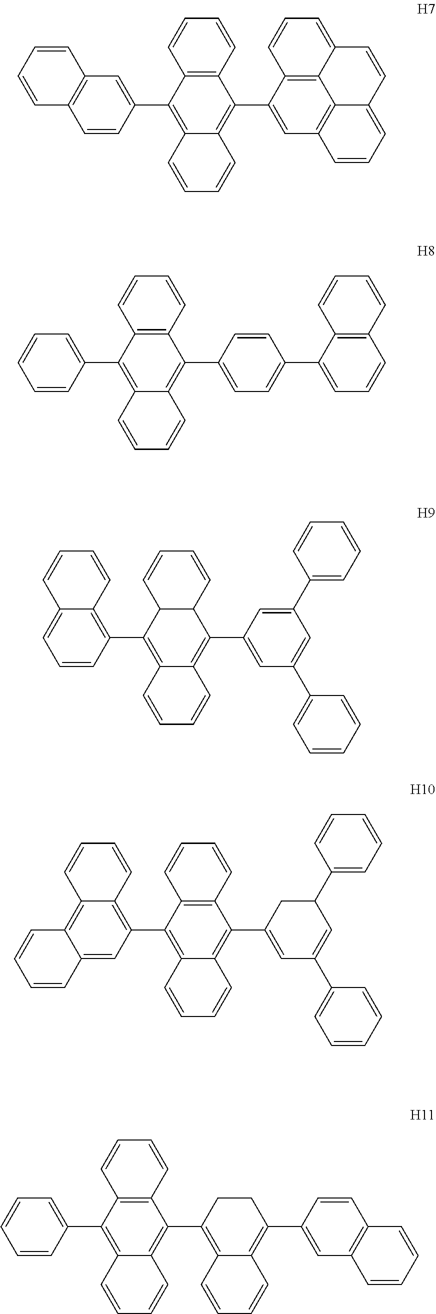

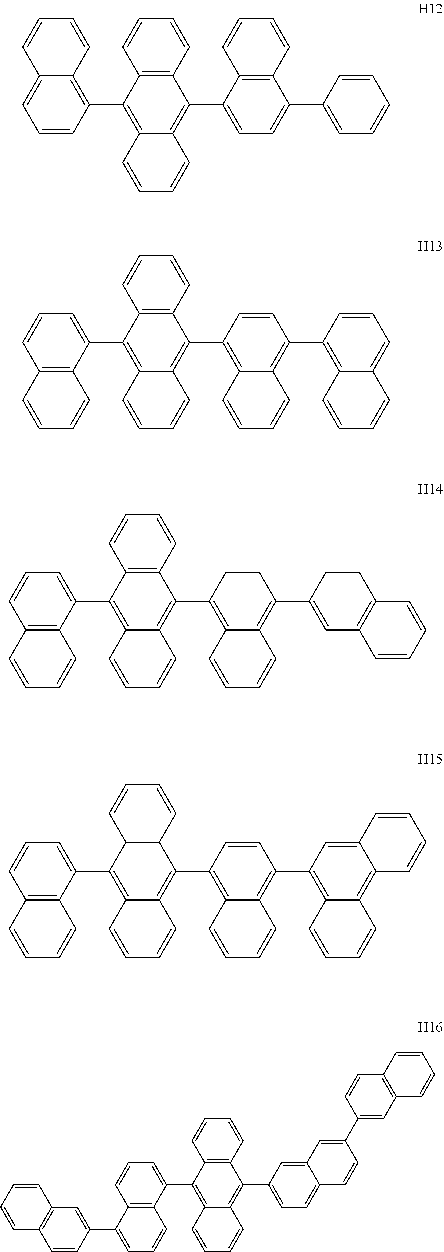

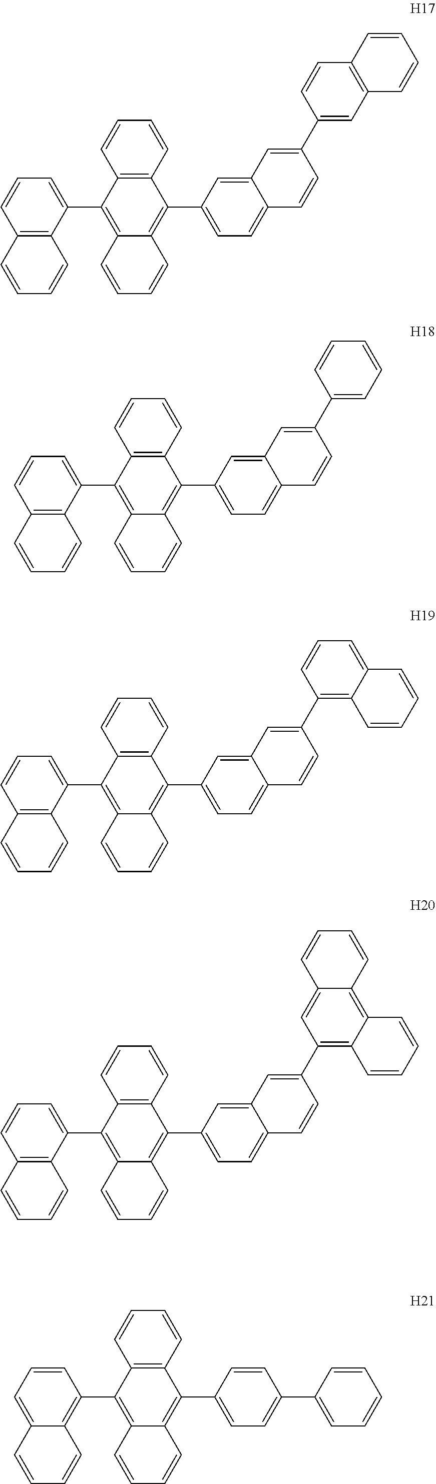

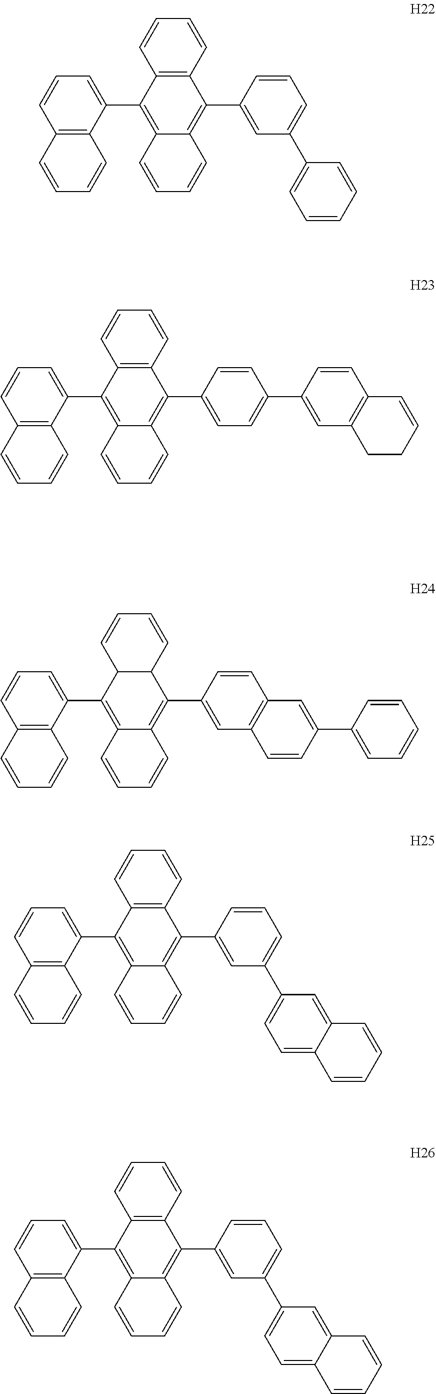

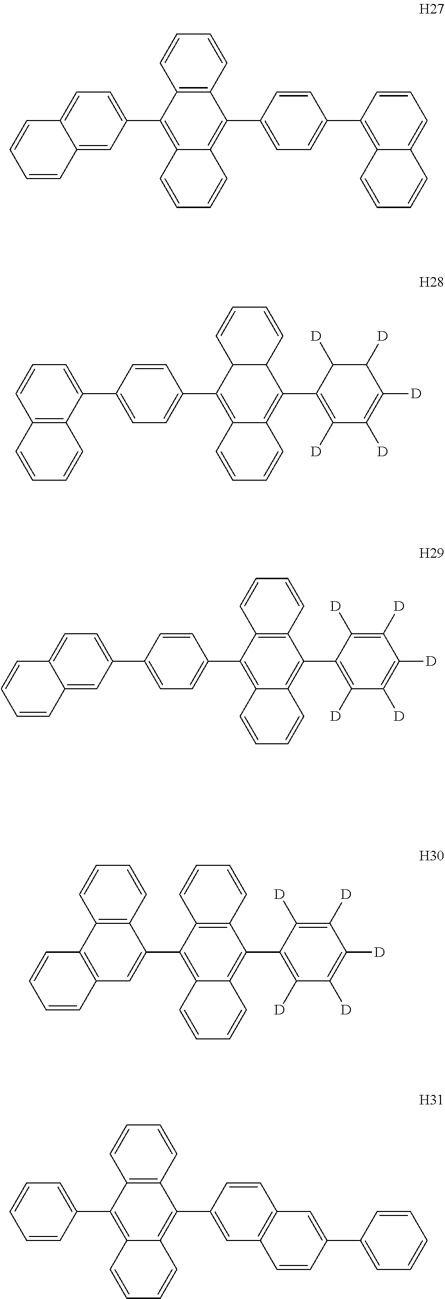

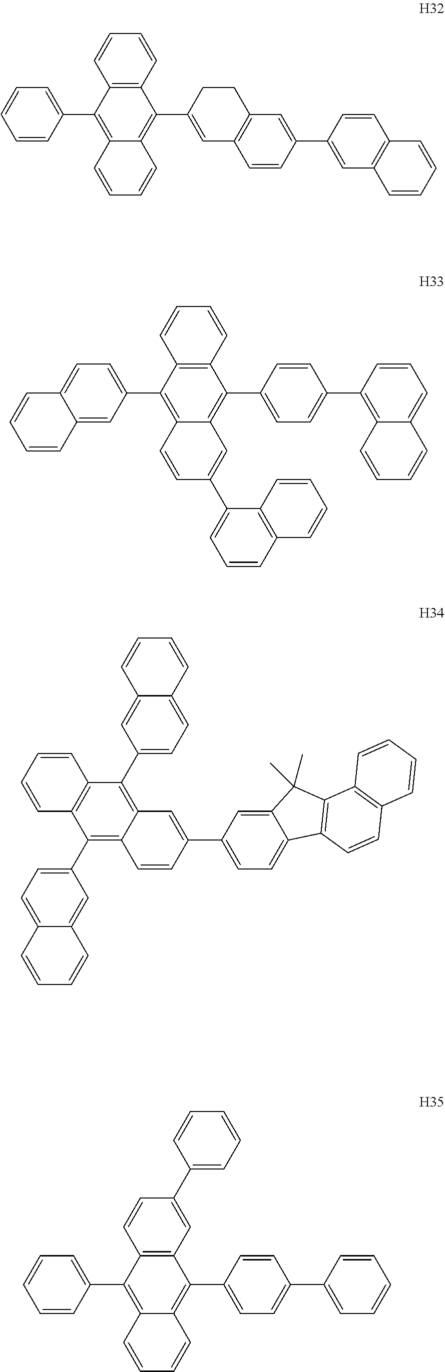

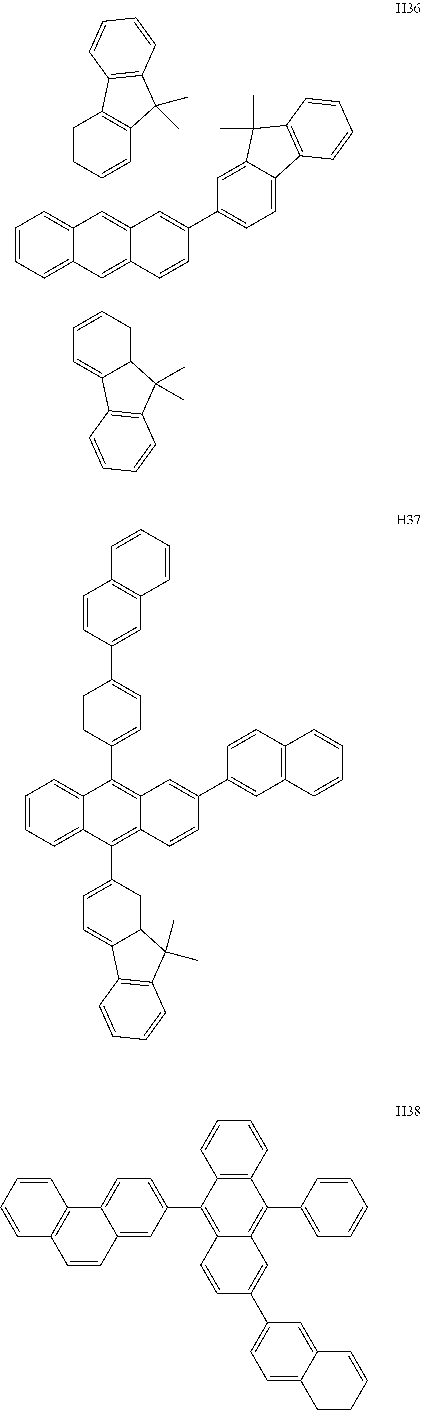

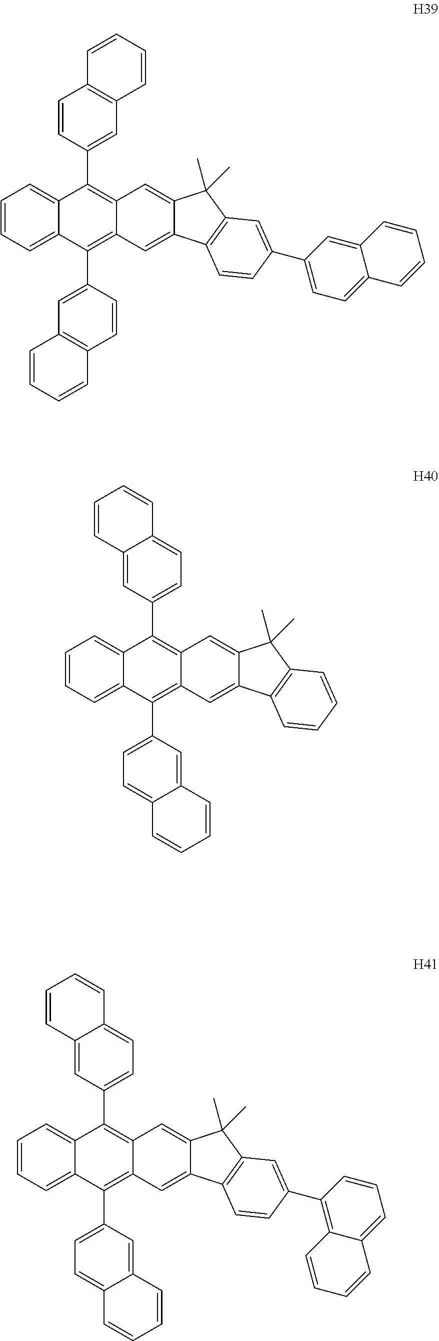

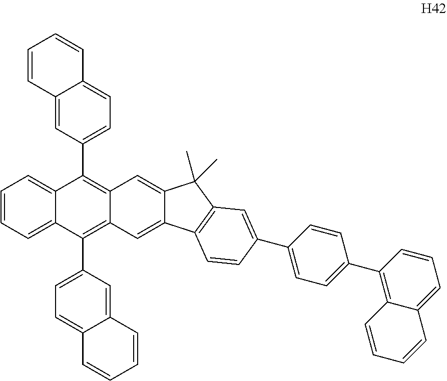 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

Also, the host may be an anthracene-based compound represented by Formula 401 below:

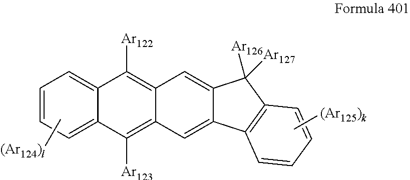

Ar₁₂₂ to Ar₁₂₅ in Formula 401 are the same as described in detail in connection with Ar₁₁₃ in Formula 400.

Ar₁₂₆ and Ar₁₂₇ in Formula 401 may be each independently a C₁-C₁₀ alkyl group (for example, a methyl group, an ethyl group, or a propyl group).

k and I in Formula 401 may be each independently an integer of 0 to 4. For example, k and I may be each independently 0, 1, or 2.

For example, the anthracene-based compound represented by Formula 401 may be one of the following compounds, but is not limited thereto:

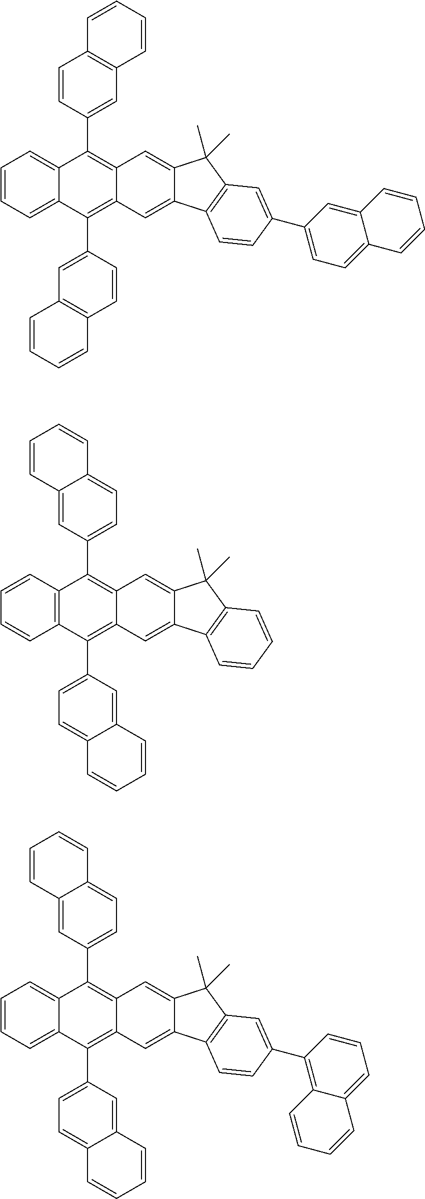

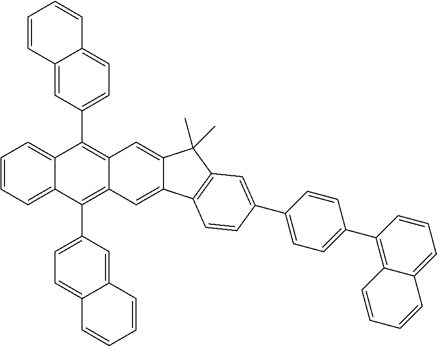 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

A dopant material may be any known (or suitable) dopant. The known (or suitable) dopant may be at least one of a fluorescent dopant and a phosphorescent dopant. The phosphorescent dopant may be an organometallic complex including Ir, Pt, Os, Re, Ti, Zr, Hf, or a combination of at least two of these, but is not limited thereto.

Examples of a known (or suitable) blue dopant are bis[3,5-difluoro-2-(2-pyridyl)phenyl](picolinato)iridium(III) (F2Irpic), (F₂ppy)₂Ir(tmd), Ir(dfppz)₃, 4,4′-bis(2,2′-diphenylethen-1-yl)biphenyl (DPVBi), 4,4′-bis[4-(diphenylamino)styryl]biphenyl (DPAVBi), and 2,5,8,11-tetra-tert-butyl perylene (TBPe), which are illustrated below:

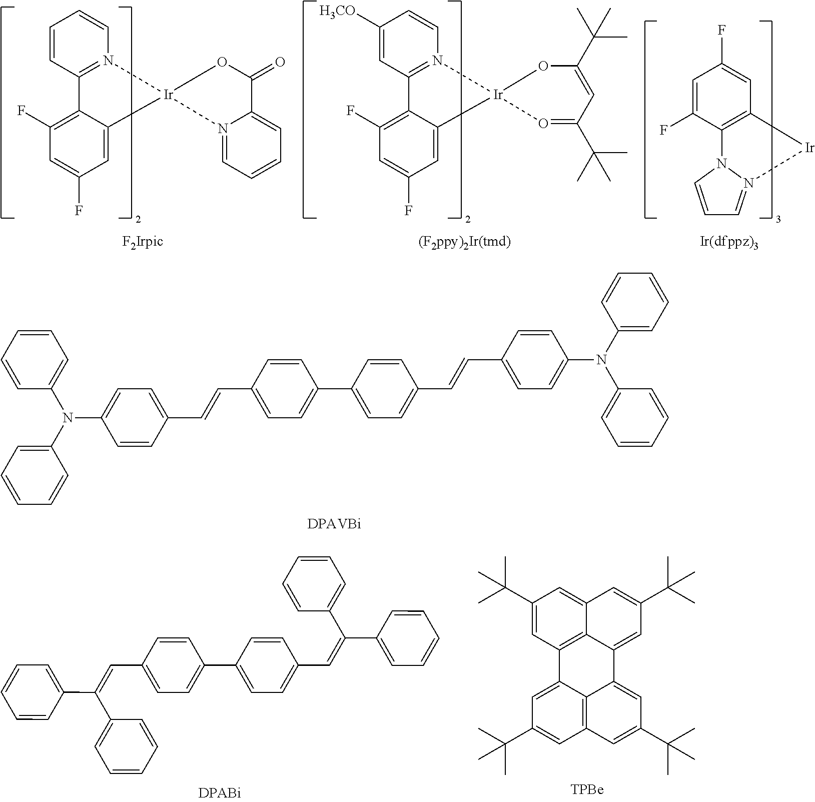

Examples of a known (or suitable) blue dopant include compounds illustrated below, but are not limited thereto:

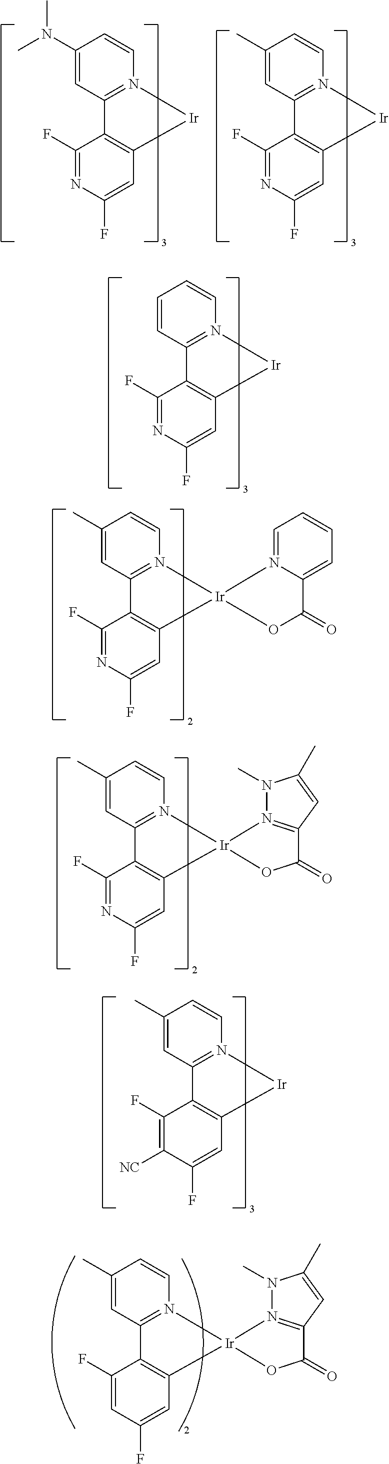

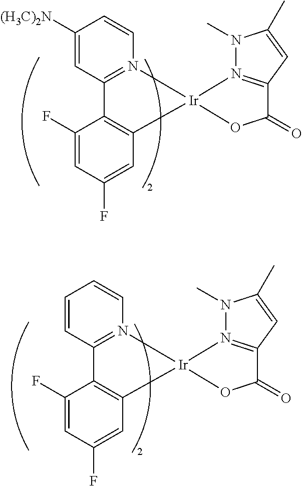

Examples of a known (or suitable) red dopant include Pt(II) octaethylporphine (PtOEP), tris(2-phenylisoquinoline)iridium (Ir(piq)3), bis(2-(2′-benzothienyI)-pyridinato-N,C3′)iridium(acetylacetonate) (Btp2Ir(acac)), 4-(dicyanomethylene)-2-methyl-6-[p-(dimethylamino)styryl]-4H-pyran (DCM), and 4-(dicyanomethylene)-2-tert-butyl-6-(1,1,7,7,-tetramethyljulolidyl-9-enyl)-4H-pyran (DCJTB), but are not limited thereto.

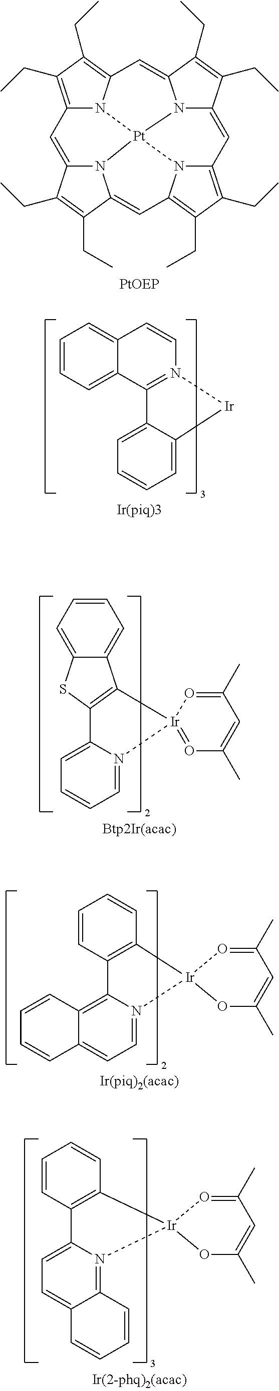

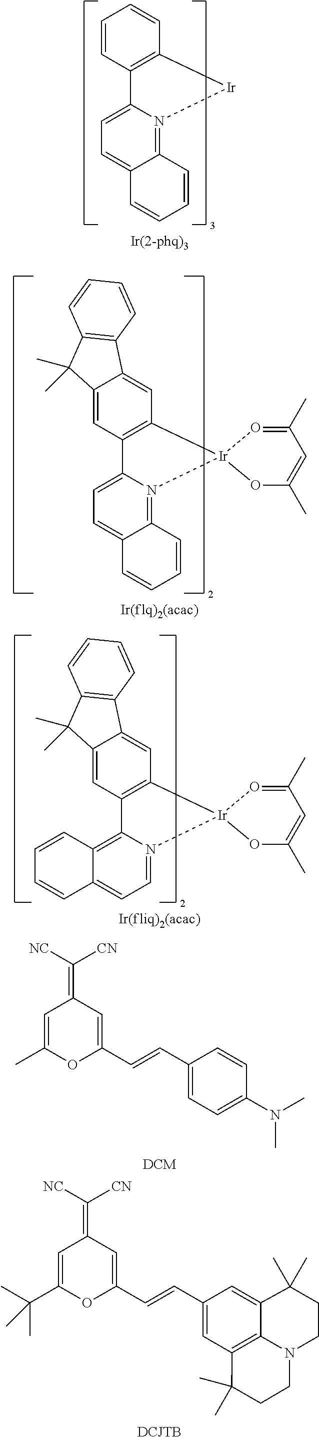

Examples of a known (or suitable) green dopant include tris(2-phenylpyridine) iridium (Ir(ppy)₃), bis(2-phenylpyridine)(acetylacetonato)iridium(III) (Ir(ppy)₂(acac)), tris(2-(4-tolyl)phenylpiridine)iridium (Ir(mppy)₃), and 10-(2-benzothiazolyl)-1,1,7,7-tetramethyl-2,3,6,7-tetrahydro-1H,5H,11H-[1]benzopyrano[6,7,8-ij]-quinolizin-11-one (C545T), but are not limited thereto.

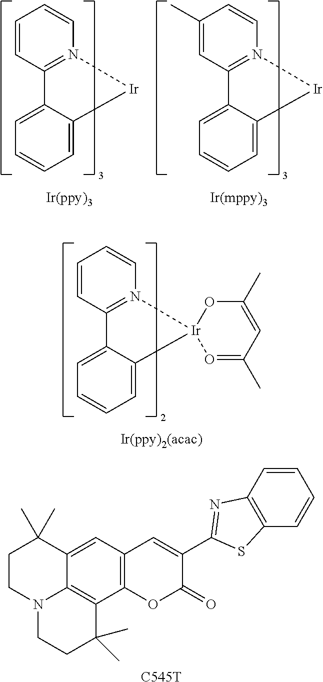

Also, the dopant available for use (usage) in the emission layer may be a Pt-complex illustrated below, but is not limited thereto:

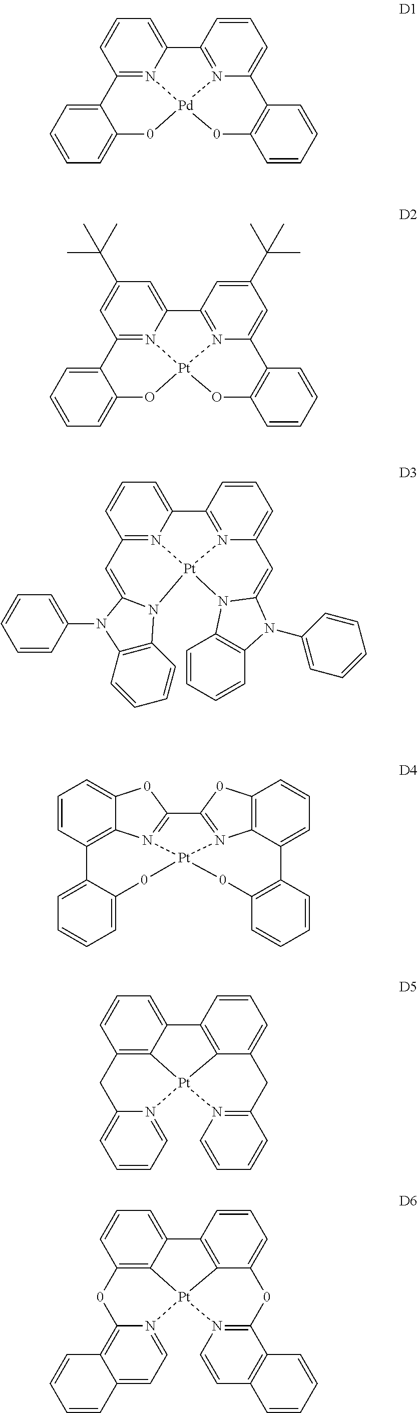

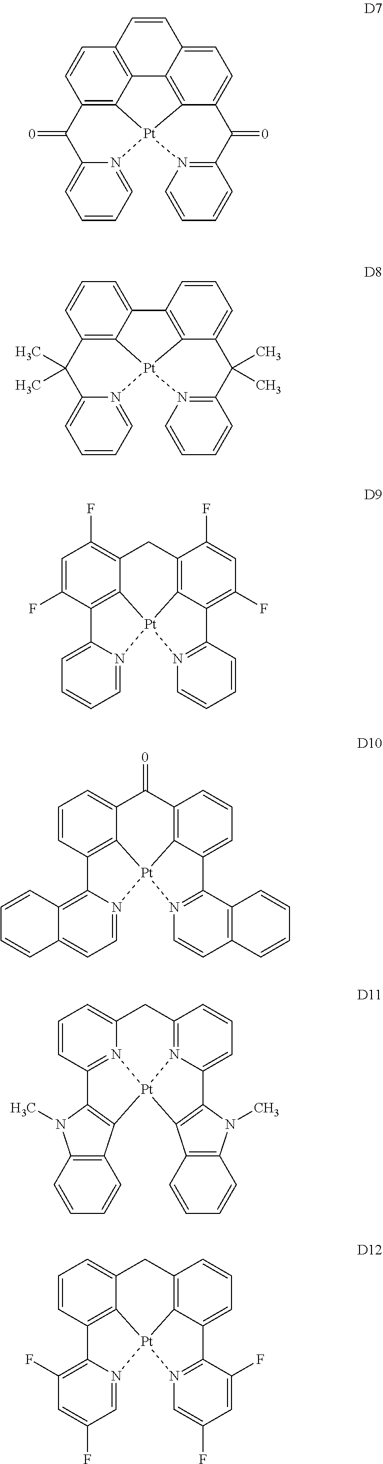

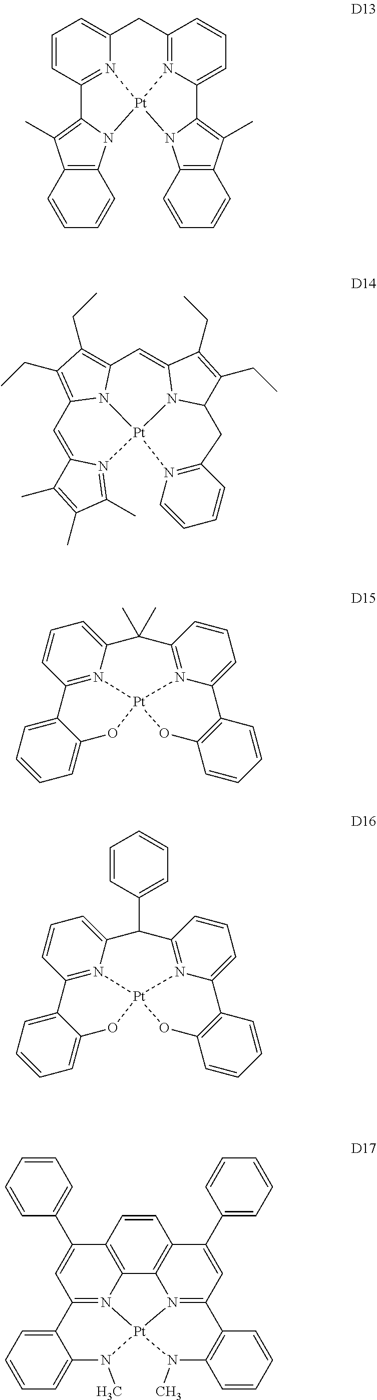

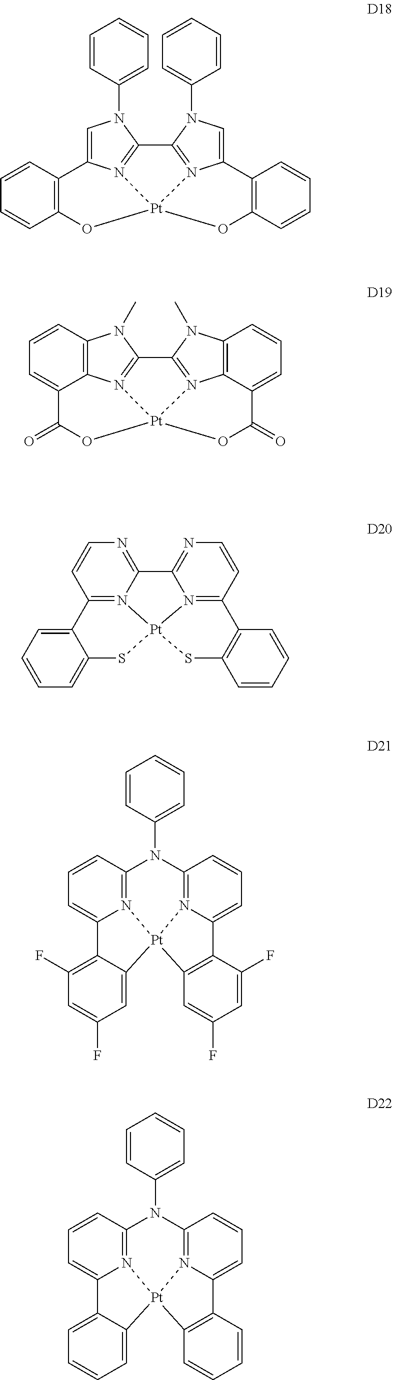

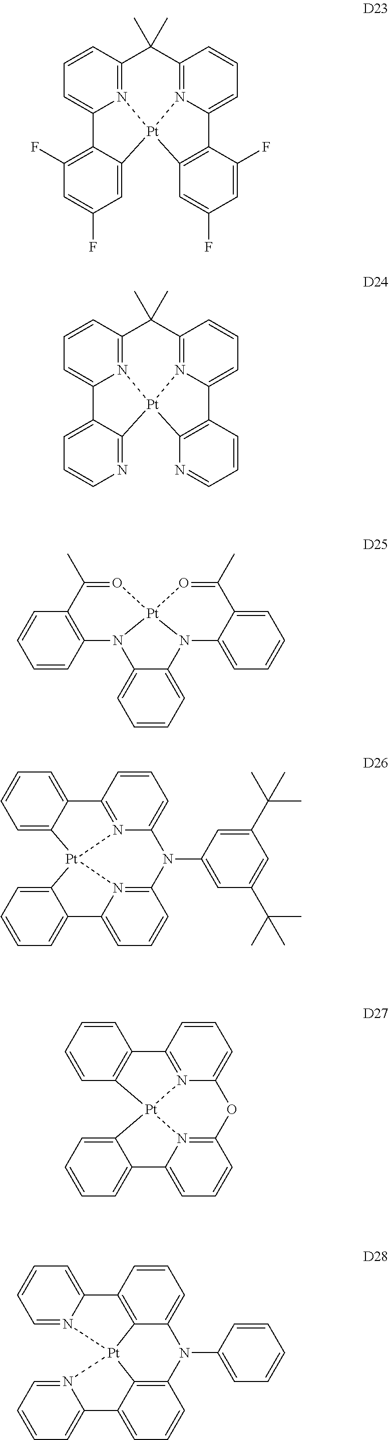

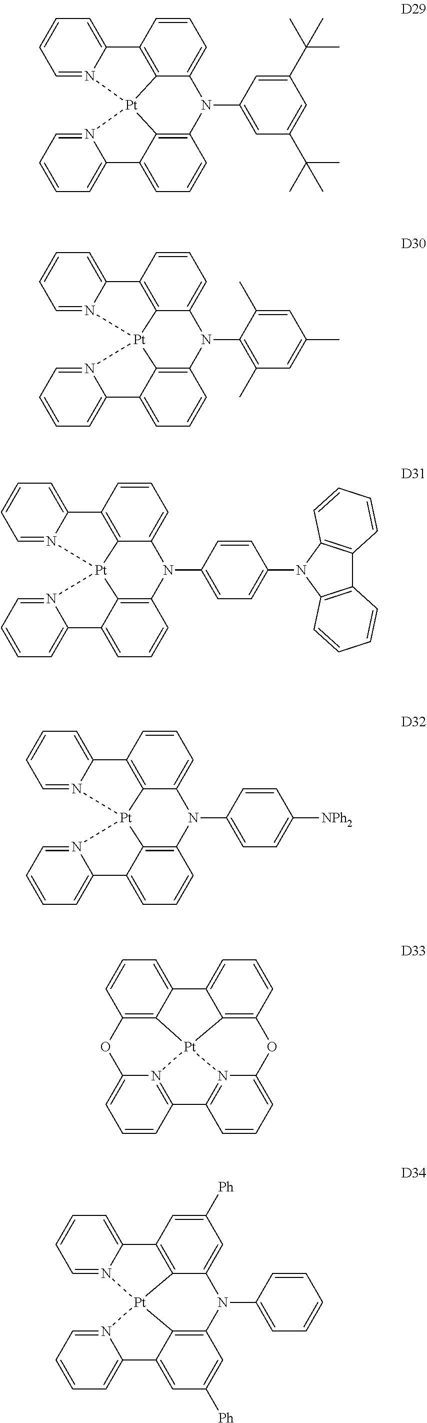

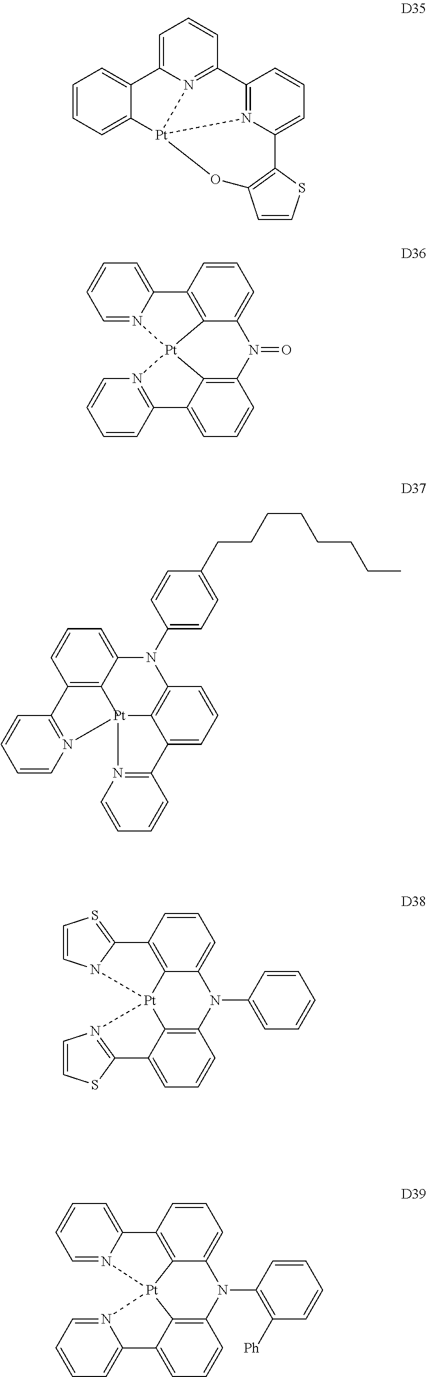

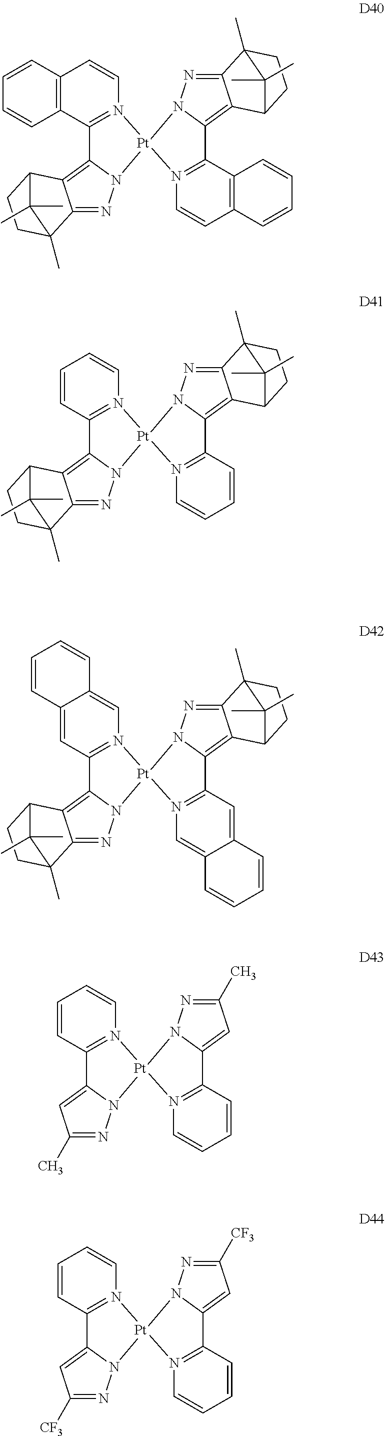

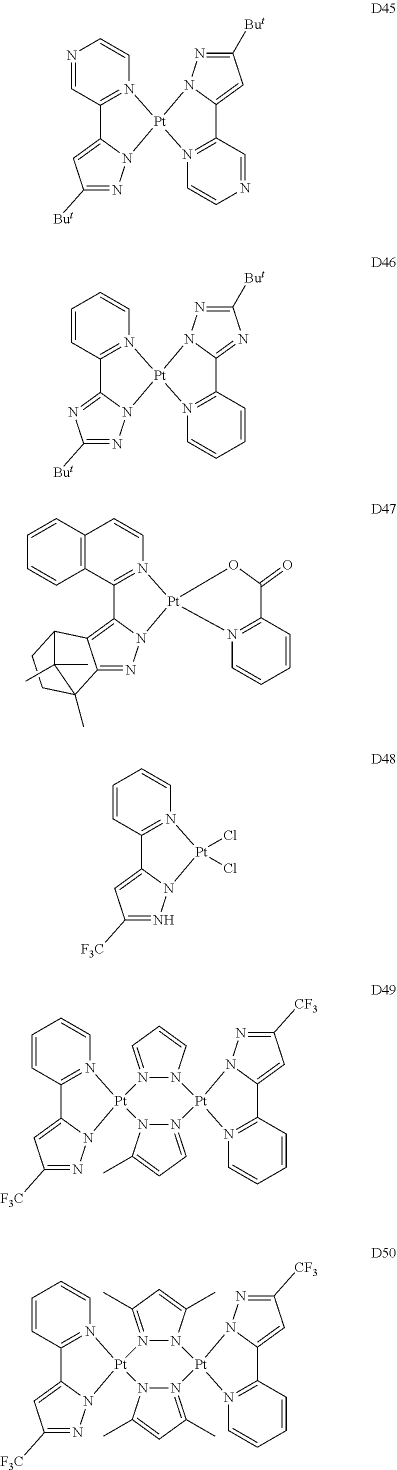

Also, the dopant available for use (usage) in the emission layer may be an Os-complex illustrated below, but is not limited thereto:

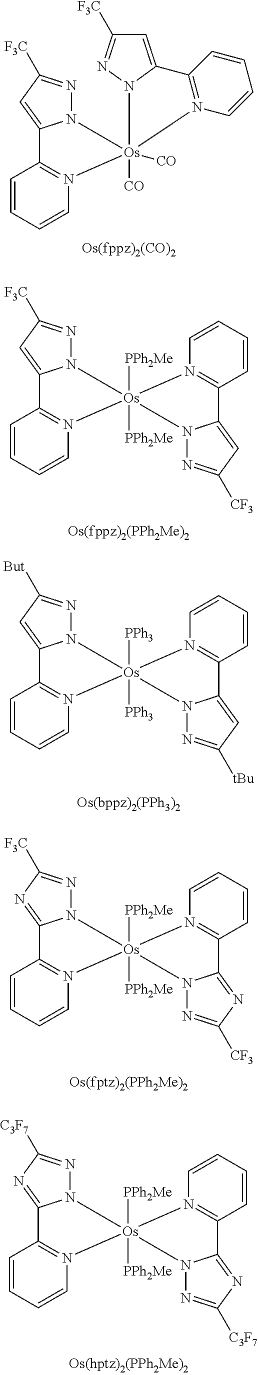

When the emission layer includes a host and a dopant, an amount of the dopant may be in a range of about 0.01 to about 15 parts by weight based on 100 parts by weight of the host, but is not limited thereto.

A thickness of the emission layer may be in a range of about 100 Å to about 1,000 Å, for example, about 200 Å to about 600 Å. In one embodiment, when the thickness of the emission layer is within this range, excellent luminescent characteristics are obtained without a substantial increase in driving voltage.

In addition, a hole blocking layer (HBL) may be formed between the hole transport layer and the emission layer by vacuum deposition, spin coating, casting, LB deposition, or the like to reduce or prevent diffusion of excitons or holes into an electron transport layer. When the hole blocking layer is formed by vacuum deposition or spin coating, the deposition and coating conditions may be similar to those for the formation of the hole injection layer, though the conditions for deposition and coating may vary according to the material that is used (utilized) to form the hole blocking layer. A hole blocking material may be any one of known (or suitable) hole blocking materials, and examples thereof are an oxadiazole derivative, a triazole derivative, a phenanthroline derivative, and so on. For example, BCP may be used (utilized) to form the hole blocking layer.

A thickness of the hole blocking layer may be in a range of about 50 Å to about 1,000 Å, for example, about 100 Å to about 300 Å. In one embodiment, when the thickness of the hole blocking layer is within these ranges, the hole blocking layer has excellent hole blocking characteristics without a substantial increase in driving voltage.

A buffer layer including the condensed cyclic compound of Formula 1 may be formed on the emission layer by, for example, vacuum deposition, spin coating, or casting. When the buffer layer is formed by vacuum deposition or spin coating, the vacuum deposition and coating conditions may be similar to those for the formation of the hole injection layer, though the conditions for vacuum deposition and coating may vary according to the material that is used (utilized) to form the buffer layer.

The buffer layer including the condensed cyclic compound of Formula 1 has excellent energy band matching characteristics with respect to an emission layer, and allows electrons to be easily supplied, thereby improving the color change in a relatively low-gradation region.

Next, an electron transport layer (ETL) is formed on the emission layer by using (utilizing) various suitable methods, for example, by vacuum deposition, spin coating, casting, or the like. When the electron transport layer is formed by vacuum deposition or spin coating, the vacuum deposition and coating conditions may be similar to those for the formation of the hole injection layer, though the conditions for vacuum deposition and coating may vary according to the material that is used (utilized) to form the electron transport layer. A material for forming the electron transport layer may stably transport electrons injected from an electron injection electrode (cathode), and may be a known (or suitable) electron transportation material.

Examples of the known (or suitable) electron transportation material are a quinoline derivative, such as Alq₃, 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), BAIq (illustrated below), beryllium bis(benzoquinolin-10-olate) (Bebq2), 9,10-di(naphthalene-2-yl)anthracene (ADN), Compound 501, and Compound 502, but are not limited thereto.

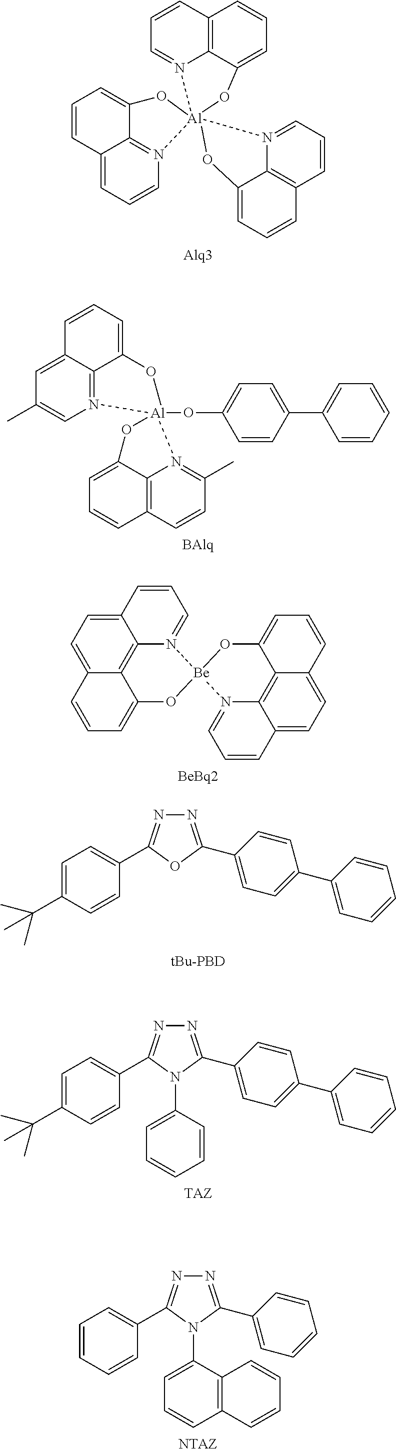

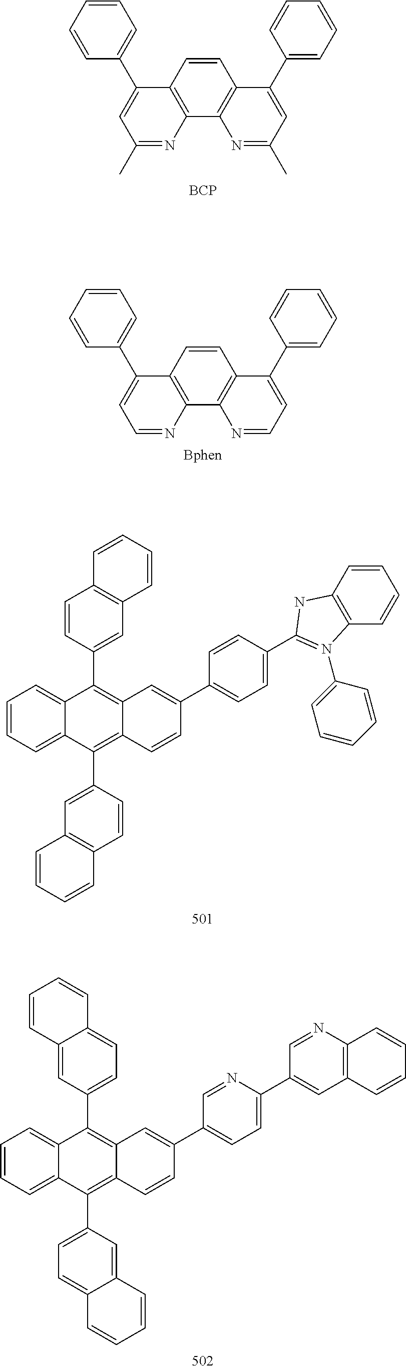

A thickness of the electron transport layer may be in a range of about 100 Å to about 1,000 Å, for example, about 150 Å to about 500 Å. In one embodiment, when the thickness of the electron transport layer is within the range described above, the electron transport layer has satisfactory electron transport characteristics without a substantial increase in a driving voltage.

In some embodiments, the electron transport layer may include an electron transport organic compound and a metal-containing material. The metal-containing material may include a Li complex. Non-limiting examples of the Li complex are lithium quinolate (LiQ) and Compound 503 illustrated below:

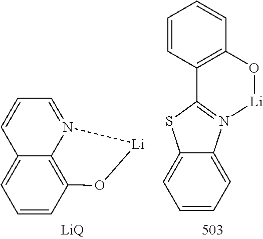

Then, an electron injection layer (EIL), which facilitates injection of electrons from the cathode, may be formed on the electron transport layer. Any suitable electron injection material may be used (utilized) to form the electron injection layer.

Non-limiting examples of materials for forming the electron injection layer are LiF, NaCl, CsF, Li₂O, and BaO, which are known in the art. The deposition conditions of the electron injection layer may be similar to those used (utilized) to form the hole injection layer, although the deposition conditions may vary according to the material that is used (utilized) to form the electron injection layer.

A thickness of the electron injection layer may be in a range of about 1 Å to about 100 Å, for example, about 3 Å to about 90 Å. In one embodiment, when the thickness of the electron injection layer is within the range described above, the electron injection layer has satisfactory electron injection characteristics without a substantial increase in a driving voltage.

The second electrode 17 is disposed on the organic layer 15. The second electrode may be a cathode that is an electron injection electrode, and in this regard, a metal for forming the second electrode may be a material having a low work function, examples thereof are metal, alloy, an electrically conductive compound, and a mixture thereof. For example, lithium (Li), magnesium (Mg), aluminum (Al), aluminum-lithium (Al—Li), calcium (Ca), magnesium-indium (Mg—In), or magnesium-silver (Mg—Ag) may be formed as a thin film for use (usage) as a transmissive electrode. Also, in the case of a top emission light-emitting device, ITO or IZO may be used (utilized) to form a transmissive electrode.

Hereinafter, an organic light-emitting device according to an embodiment is described in more detail with reference to the Synthesis Examples and Examples. However, the organic light-emitting device is not limited thereto.

### SYNTHESIS EXAMPLE 1

### Synthesis of Compound 1

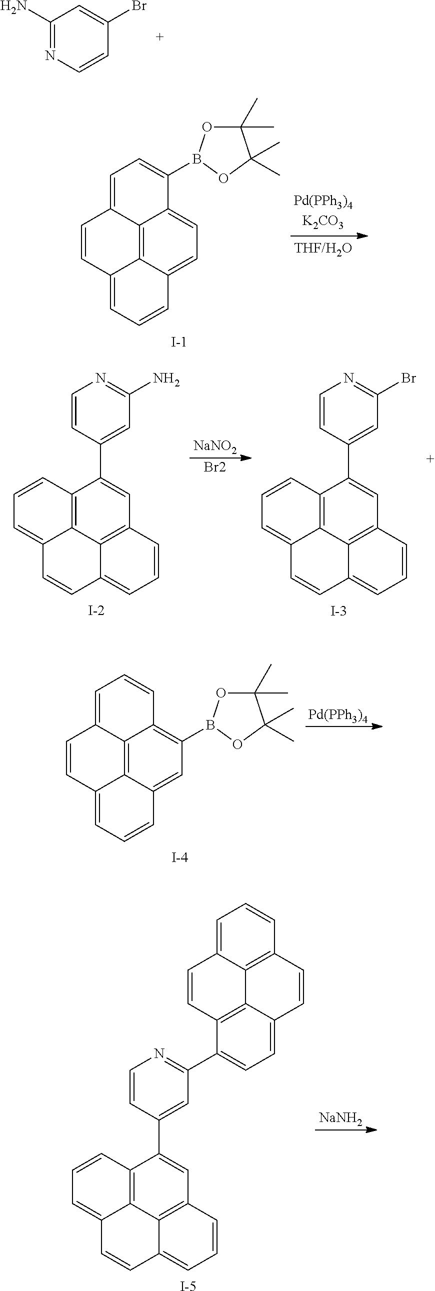

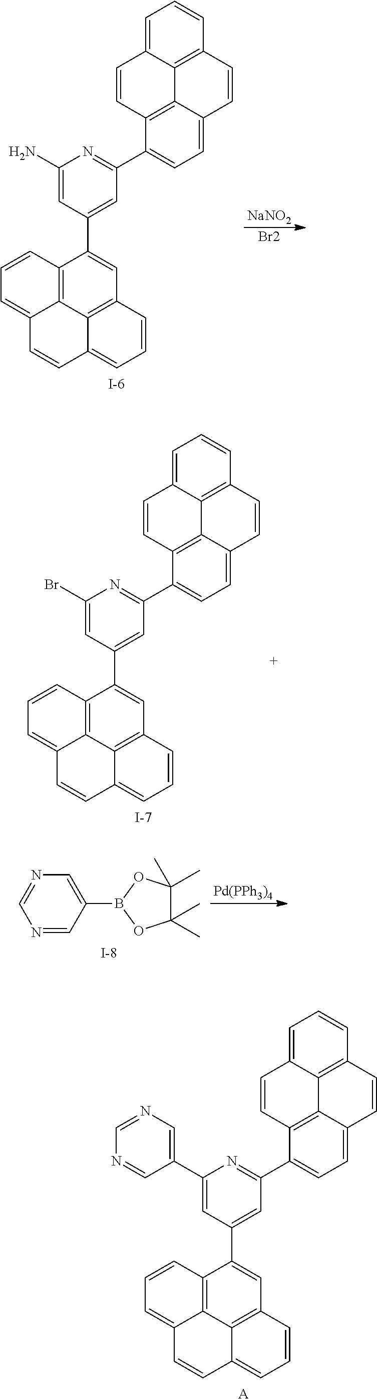

### Synthesis of Intermediate I-2

39.39 g (120.0 mmol) of Intermediate I-1, 10.38 g (60.0 mmol) of 2-amino-4-bromopyridine, 3.47 g (3.0 mmol) of Pd(PPh₃)₄, and 24.84 g (180.0 mmol) of K₂CO₃ were dissolved in 75 mL of a THF/H₂O mixed solution (a volumetric ratio of 2/1), and then, at a temperature of 70° C., the resultant solution was stirred for 5 hours. The reaction solution was cooled to room temperature, and then extracted three times with 100 mL of water and 100 mL of diethylether. A collected organic layer was dried by using (utilizing) magnesium sulfate, and then, the residual obtained by evaporating the solvent therefrom was separation-purified by silica gel column chromatography to obtain 18.84 g (yield of 80%) of Intermediate I-2. The obtained compound was identified by LC-MS. (C₂₁H₁₄N₂: calc. 294.36, obtained 294.12)

### Synthesis of Intermediate I-3

22.08 g (75 mmol) of Intermediate I-2 was mixed with 9.6 mL (48%) of a hydrobromic acid (HBr), and then, the temperature was dropped to −2° C., and 3.9 mL (49 mmol) of bromine (Br₂) was added thereto. 2.8 g (41 mmol) of sodium nitrite (NaNO₂) was added thereto in a nitrogen atmosphere, and then, 15 mL of 30% sodium hydroxide was added thereto. The mixture was stirred for 20 minutes. 15 minutes after the stirring, extraction was performed three times thereon with 150 mL of ether. A collected organic layer was dried by using (utilizing) sodium sulfate, and then, the residual obtained by evaporating the solvent therefrom was separation-purified by silica gel column chromatography to obtain 17.73 g (yield of 66%) of Intermediate I-3. The obtained compound was identified by LC-MS. (C₃₇H₂₂N₂: calc. 358.24, obtained 357.02)

### Synthesis of Intermediate I-5

26.26 g (80.0 mmol) of Intermediate I-4, 13.13 g (40.0 mmol) of Intermeidate I-3, 2.3 g (2.0 mmol) of Pd(PPh₃)₄, and 16.58 g (120.0 mmol) of K₂CO₃ were dissolved in 50 mL of a THF/H₂O (2/1) mixed solution, and then, at a temperature of 70° C., the resultant solution was stirred for 5 hours. The reaction solution was cooled to room temperature, and then extracted three times with 100 mL of water and 100 mL of diethylether. A collected organic layer was dried by using (utilizing) magnesium sulfate, and then, the residual obtained by evaporating the solvent therefrom was separation-purified by silica gel column chromatography to obtain 15.34 g (yield of 80%) of Intermediate I-5. The obtained compound was identified by LC-MS. (C₃₇H₂₁N: calc. 479.58, obtained 479.17)

### Synthesis of Intermediate I-6

11.99 g (25 mmol) of Intermediate I-5 and 2.4 g of sodium amide were dissolved in 10.5 mL of dimethylaniline, and then, the mixture was stirred in an argon atmosphere at a temperature of 118° C. for 18 hours. The reaction solution was cooled to room temperature, and then, 13 mL of 5% sodium hydroxide solution and 40 mL of water were added thereto, and the result was stirred for 15 minutes. To remove dimethylaniline, extraction was performed thereon with 25 mL of petroleum ether. Sodium hydroxide was added to the resultant mixture, cooled, and then subjected to extraction three times by using (utilizing) 50 mL of benzene to obtain 8.2 g (yield of 66%) of Intermediate I-6. The obtained compound was identified by LC-MS. (C₃₇H₂₂N₂: calc. 494.60, obtained 494.18)

### Synthesis of Intermediate I-7

7.91 g (16 mmol) of Intermediate I-6 was mixed with 9.6 mL (48%) of a hydrobromic acid, and then, the temperature was dropped to −2° C., and 3.9 mL (49 mmol) of bromine was added thereto. 2.8 g (41 mmol) of sodium nitrite (NaNO₂) was added thereto in a nitrogen atmosphere, and then, 15 mL of 30% sodium hydroxide was added thereto. The mixture was stirred for 20 minutes. 15 minutes after the stirring, extraction was performed three times thereon with 150 mL of ether. A collected organic layer was dried by using (utilizing) sodium sulfate, and then, the residual obtained by evaporating the solvent therefrom was separation-purified by silica gel column chromatography to obtain 5.58 g (yield of 62%) of Intermediate I-7. The obtained compound was identified by LC-MS. (C₃₇H₂₀BrN: calc. 558.48, obtained 557.08)

### Synthesis of Compound 1 (i.e., Compound A)

5.58 g (10.0 mmol) of Intermediate I-7, 2.06 g (10.0 mmol) of Intermeidate I-8, 0.75 g (0.5 mmol) of Pd(PPh₃)₄, and 4.15 g (30.0 mmol) of K₂CO₃ were dissolved in 25 mL of a THF/H₂O (2/1) mixed solution, and then, at a temperature of 70° C., the resultant solution was stirred for 5 hours. The reaction solution was cooled to room temperature, and then extracted three times with 25 mL of water and 25 mL of diethylether. A collected organic layer was dried by using (utilizing) magnesium sulfate, and then, the residual obtained by evaporating the solvent therefrom was separation-purified by silica gel column chromatography to obtain 4.46 g (yield of 80%) of Compound 1 (i.e., Compound A). The obtained compound was identified by LC-MS. (C₄₁H₂₃N₃: calc. 557.66, obtained 557.19)

### SYNTHESIS EXAMPLE 2

### Synthesis of Compound 2 (i.e., Compound B)

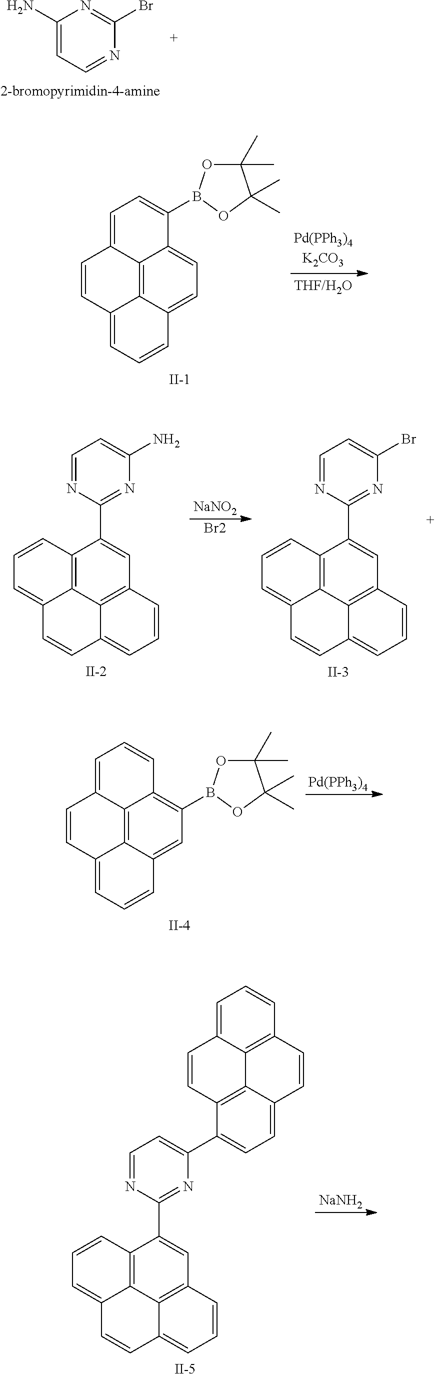

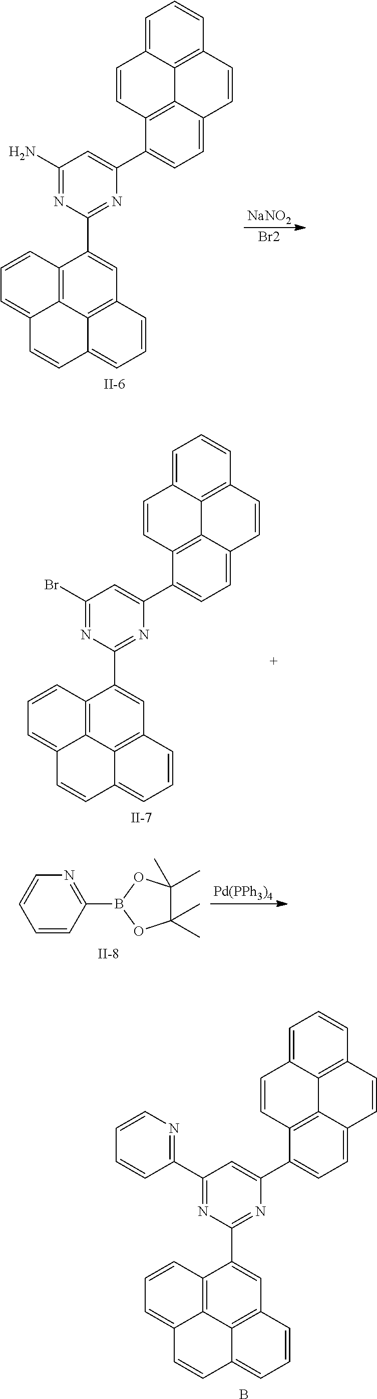

Intermediate II-2 was synthesized in the same manner as used (utilized) to synthesize Intermediate I-2, except that 6-bromo-4-aminopyrimidine was used (utilized) instead of 2-amino-4-bromopyridine.

Compound 2 (i.e., Compound B) was obtained in the same manner as used (utilized) to synthesize Compound 1, except that Intermediate II-2 was used (utilized) instead of Intermediate I-2, and Intermediate II-8 was used (utilized) instead of Intermediate I-8. (C₄₁H₂₃N₃: calc. 557.66, obtained 557.19)

### SYNTHESIS EXAMPLE 3

### Synthesis of Compound 3 (i.e., Compound C)

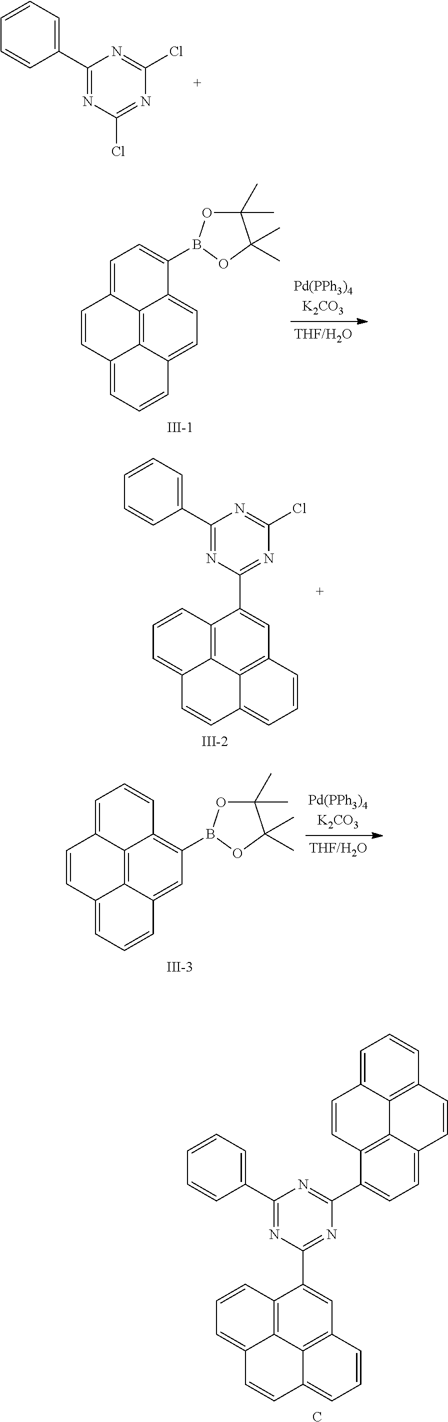

### Synthesis of Intermediate III-2

19.69 g (60.0 mmol) of Intermediate III-1, 13.56 g (60.0 mmol) of 2,4-dichloro-6-phenyl-1,3,5-triazine, 1.73 g (1.5 mmol) of Pd(PPh₃)₄, and 12.44 g (90.0 mmol) of K₂CO₃ were dissolved in 75 mL of a THF/H₂O mixed solution (a volumetric ratio of 2/1), and then, at a temperature of 70° C., the resultant solution was stirred for 5 hours. The reaction solution was cooled to room temperature, and then extracted three times with 100 mL of water and 100 mL of diethylether. A collected organic layer was dried by using (utilizing) magnesium sulfate, and then, the residual obtained by evaporating the solvent therefrom was separation-purified by silica gel column chromatography to obtain 23.51 g (yield of 50%) of Intermediate III-2. The obtained compound was identified by LC-MS. (C₂₁H₁₄N₂: calc. 391.86, obtained 391.09)

### Synthesis of Compound 3 (i.e., Compound C)

19.59 g (50.0 mmol) of Intermediate III-2, 16.41 g (50.0 mmol) of Intermediate III-3, 1.73 g (1.5 mmol) of Pd(PPh₃)₄, and 12.44 g (90.0 mmol) of K₂CO₃ were dissolved in 75 mL of a THF/H₂O mixed solution (a volumetric ratio of 2/1), and then, at a temperature of 70° C., the resultant solution was stirred for 5 hours. The reaction solution was cooled to room temperature, and then extracted three times with 100 mL of water and 100 mL of diethylether. A collected organic layer was dried by using (utilizing) magnesium sulfate, and then, the residual obtained by evaporating the solvent therefrom was separation-purified by silica gel column chromatography to obtain 22.30 g (yield of 80%) of Compound 3 (i.e., Compound C). The obtained compound was identified by LC-MS. (C₂₁H₁₄N₂: calc. 557.66, obtained 557.19)

### EXAMPLE 1

An anode was manufactured as follows: an ITO glass substrate (a product of Corning Co., Ltd) having an ITO layer having a thickness of 1200 Å and a sheet resistance of 150 Ω/cm² was cut to a size of 50 mm×50 mm×0.7 mm, and then, sonicated by using (utilizing) isopropyl alcohol for 5 minuts and pure water for 5 minutes, and cleaned by exposure to ultraviolet rays and ozone for 30 minutes. 2-TNATA was vacuum deposited on the ITO glass substrate to form a hole injection layer having a thickness of 600 Å, and then, NPB was vacuum deposited on the hole injection layer to form a hole transport layer having a thickness of 300 Å. 98 wt % of ADN, which is a blue fluorescent host, and 2 wt % of DPAVBi, which is a blue fluorescent dopant, were used (utilized) to form an emission layer having a a thickness of 300 Å on the hole transport layer. Compound 1 was vacuum deposited on the emission layer to form a buffer layer having a thickness of 40 Å. Alq₃ was vacuum deposited on the buffer layer to form an electron transport layer having a thickness of 320 Å. LiF was vacuum deposited on the electron transport layer to form an electron injection layer having a thickness of 10 Å, and then, Al was vacuum deposited thereon to form a cathode having a thickness of 3,000 Å, thereby completing the manufacturing of an organic light-emitting device.

### COMPARATIVE EXAMPLE 1

An organic light-emitting device was manufactured in the same manner as in Example 1, except that the electron transport layer was formed to have a thickness of 360 Å without utilizing the buffer layer.

### EXAMPLE 2

An organic light-emitting device was manufactured in the same manner as in Example 1, except that as a material for forming the buffer layer, Compound 2 was used (utilized) instead of Compound 1.

### EXAMPLE 3

An organic light-emitting device was manufactured in the same manner as in Example 1, except that as a material for forming the buffer layer, Compound 3 was used (utilized) instead of Compound 1.

### EVALUATION EXAMPLE

The driving voltage, current density, luminance, efficiency, and emission color of the organic light-emitting devices manufactured according to Examples 1 to 3 and Comparative Example 1 were measured in the following manners.

1) Change in Current Density According to Voltage

Regarding the organic light-emitting devices, a current flowing in a unit device was measured by using (utilizing) a current-voltage meter while a voltage was raised, and the measured current value was divided by an area.

2) Change in Luminance According to Voltage

Regarding the organic light-emitting device, luminance was measured by using (utilizing) Minolta Cs-1000A, which is a luminance meter, while a voltage was raised.

3) Luminescent Efficiency and Power Efficiency Measurement

Luminance values, current densities, and voltages (V) which were measured in 1) (change in current density according to voltage) and 2) (change in brightness according to voltage) were used (utilized) to calculate current efficiency and power efficiency, and results are shown in Table 1.

4) Lifespan Measurement

From among current density values according to voltage, a current value corresponding to a reference luminance (blue 720nit) was identified, and then, at a constant current, brightness change was measured according to time by using (utilizing) a lifespan measurement equipment (OLED Life Time System). The lifespan was determined as a time when an emission luminance of a device was dropped to 97% of the initial emission luminance.

TABLE 1

| | Driving | Current | Current | Power | Color | Color | Lifespan |
|---|---|---|---|---|---|---|---|
| | voltage | density | efficiency | Efficiency | coordinate | coordinate | (time @ |
| | (V) | (mA/cm²) | (cd/A) | (lm/W) | (CIE_x) | (CIE_y) | % L = 97) |
| Comparative | 4.9 | 11.7 | 5.7 | 3.6 | 0.138 | 0.051 | 400 |
| Example 1 | | | | | | | |
| Example 1 | 4.9 | 11.6 | 5.1 | 3.3 | 0.140 | 0.046 | 405 |
| Example 2 | 4.8 | 12.4 | 4.5 | 2.9 | 0.142 | 0.042 | 395 |
| Example 3 | 4.8 | 12.0 | 5.0 | 3.2 | 0.141 | 0.045 | 402 |

Referring to Table 1, the driving voltage, efficiency, and lifespan of the organic light-emitting devices of Examples 1 to 3 are similar to those of the organic light-emitting device of Comparative Example 1.

FIG. 2 is a graph of current efficiency with respect to luminance of the organic light-emitting devices of Comparative Example 1 and Examples 1 to 3. Referring to FIG. 2, in the case of Comparative Example 1, the current efficiency was not constant (e.g., in a low luminance region (0 to 30 cd/m²), a maximum value of the current efficiency is 6.2 Cd/A, while in a high luminance region, the value of the currently efficiency is lower). However, in the case of Examples 1 to 3, the maximum value and the average value of luminance were almost constant (e.g., about the same).

That is, in organic light-emitting devices according to embodiments of the present invention, electrons are easily provided from a buffer layer into an emission layer, and luminescent efficiency in a relatively low-gradation region is stabilized. Accordingly, the organic light-emitting devices have improved color change.

An organic light-emitting device including the condensed cyclic compound of Formula 1 has excellent performances and improved color change in a relatively low-gradation region.

It should be understood that the example embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims, and equivalents thereof.

What is claimed is:

1. A condensed cyclic compound represented by Formula 1 below: 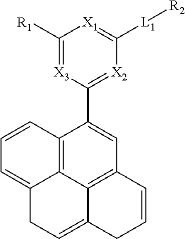
wherein in Formula 1,
X₁, X₂, and X₃ are each independently N or —CH, and at least one of X₁, X₂, and X₃ is N;
R₁ and R₂ are each independently selected from a hydrogen, a deuterium, a halogen atom, a hydroxyl group, a cyano group, a nitro group, an amino group, an amidino group, a hydrazine group; a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group;
a C₁-C₄₀ alkyl group, a C₂-C₄₀ alkenyl group, a C₂-C₄₀ alkynyl group, and a C₁-C₄₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group; and
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group;
L₁ is selected from a direct bond; a C₆-C₄₀ arylene group; a C₂-C₄₀ heteroarylene group; and a C₆-C₄₀ arylene group and a C₂-C₄₀ heteroarylene group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group, —N(Q₁₁)(Q₁₂), and —Si(Q₁₃)(Q₁₄)(Q₁₅); and
Q₁₁ to Q₁₅ are each independently selected from a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group;
a C₁-C₄₀ alkyl group, a C₂-C₄₀ alkenyl group, a C₂-C₄₀ alkynyl group, and a C₁-C₄₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group; and
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arythio group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group.

2. The condensed cyclic compound of claim 1, wherein R₁ and R₂ in Formula 1 are each independently selected from:
a hydrogen, a deuterium, a phenyl group, a pentalenyl group, an indenyl group, a naphthyl group, an azulenyl group, an indacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isooxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran group, an indolyl group, an isoindolyl group, an indolizinyl group, a benzofuryl group, an isobenzofuryl group, an indazolyl group, a benzimidazolyl group, a benzoxazolyl group, a benzisooxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a pyridoindolyl group, a dibenzofuryl group, a phenanthridinyl group, a benzoquinolyl group, a phenazinyl group, a dibenzosilolyl group, a dibenzothiophenyl group, and a benzocarbazolyl group; and
a phenyl group, a pentalenyl group, an indenyl group, a naphthyl group, an azulenyl group, an inacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isooxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran group, an indolyl group, an isoindolyl group, an indolizinyl group, a benzofuryl group, an isobenzofuryl group, an indazolyl group, a benzimidazolyl group, a benzoxazolyl group, a benzisooxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a pyridoindolyl group, a dibenzofuryl group, a phenanthridinyl group, a benzoquinolyl group, a phenazinyl group, a dibenzosilolyl group, a dibenzothiophenyl group and a benzocarbazolyl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group.

3. The condensed cyclic compound of claim 1, wherein R₁ and R₂ are each independently represented by any one of Formulae 2A to 2D below: 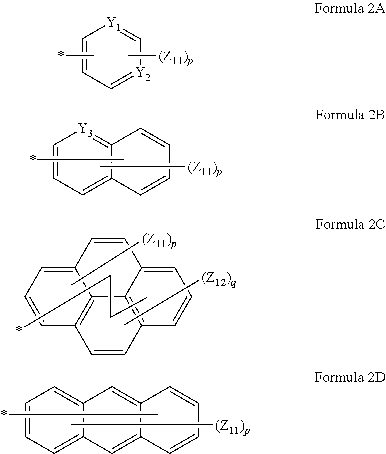
in Formulae 2A to 2D,
Y₁, Y₂, and Y₃ are each independently N or —CH;
Z₁₁ and Z₁₂ are each independently selected from a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group;
a C₁-C₂₀ alkyl group and a C₁-C₂₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof; and
a C₆-C₂₀ aryl group and a C₂-C₂₀ heteroaryl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group;
p is an integer of 3 to 9; q is 4 or 5; and * indicates a binding site.

4. The condensed cyclic compound of claim 1, wherein R₁ and R₂ are each independently represented by any one of Formulae 3A to 3J below: 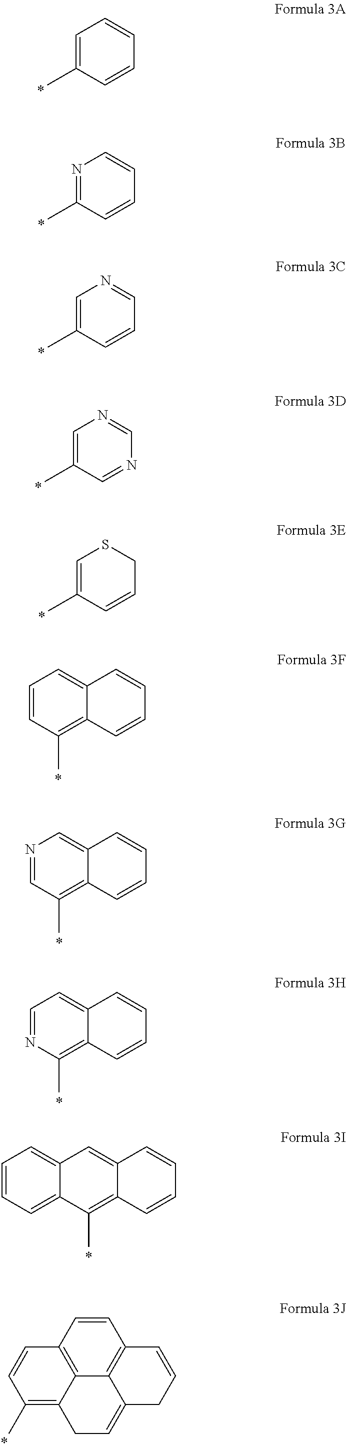
in the formulae above, * indicates a binding site.

5. The condensed cyclic compound of claim 1, wherein L₁ is selected from:
a direct bond, a phenylene group, a pentalenylene group, an indenylene group, a naphthylene group, an azulenylene group, an indacenylene group, an acenaphthylene group, a biphenylene group, a heptalenylene group, a phenalenylene group, a fluorenylene group, a phenanthrenylene group, an anthrylene group, a fluoranthenylene group, a pyrenylene group, a benzofluorenylene group, a naphthacenylene group, a chrysenylene group, and a triphenylenylene group; and
a phenylene group, a pentalenylene group, an indenylene group, a naphthylene group, an azulenylene group, an indacenylene group, an acenaphthylene group, a biphenylene group, a heptalenylene group, a phenalenylene group, a fluorenylene group, a phenanthrenylene group, an anthrylene group, a fluoranthenylene group, a pyrenylene group, a benzofluorenylene group, a naphthacenylene group, a chrysenylene group, and a triphenylenylene group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₆-C₄₀ aryloxy group, and a C₆-C₄₀ arylthio group.

6. The condensed cyclic compound of claim 1, wherein L₁ is a direct bond or any one represented by Formulae 4A and 4B: 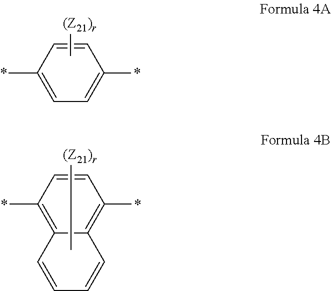
wherein in Formulae 4A and 4B,
Z₂₁ is independently selected from a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₂-C₂₀ alkyl group, a C₁-C₂₀ alkoxy group, a C₆-C₂₀ aryl group, and a C₂-C₂₀ heteroaryl group;
a C₁-C₂₀ alkyl group and a C₁-C₂₀ alkoxy group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof; and
a C₆-C₂₀ aryl group and a C₂-C₂₀ heteroaryl group, each substituted with at least one of a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, and a C₂-C₂₀ heteroaryl group;
r is an integer of 4 to 6; and * indicates a binding site.

7. The condensed cyclic compound of claim 1, wherein L₁ is a direct bond or any one represented by Formulae 5A and 5B: 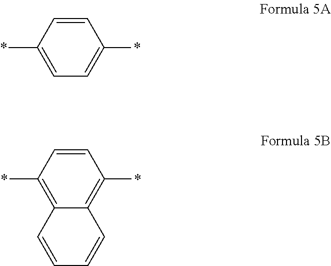 [SMILES: *c1ccc(*)cc1 ; *c1ccc(*)c2ccccc12]
in Formulae 5A and 5B, * indicates a binding site.

8. The condensed cyclic compound of claim 1, wherein the condensed cyclic compound is represented by any one of Formulae 1A to 1C: 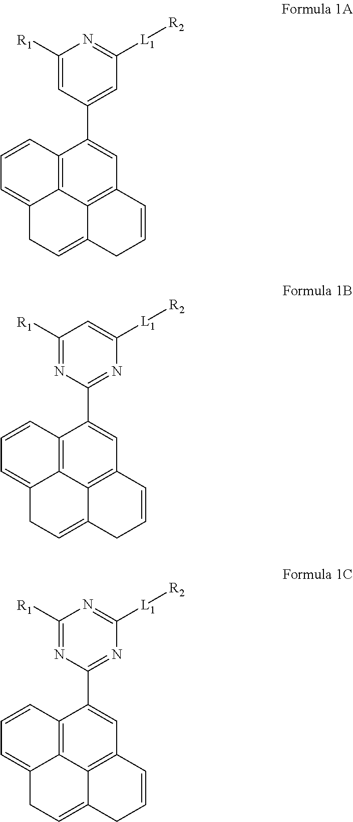
in Formulae 1A to 1C,
R₁ and R₂ are each independently selected from a C₆-C₄₀ aryl group and a C₂-C₄₀ heteroaryl group; and
L₁ is selected from a direct bond, a C₆-C₄₀ arylene group, and a C₂-C₄₀ heteroarylene group.

9. The condensed cyclic compound of claim 8, wherein R₁ and R₂ are each independently selected from:
a phenyl group, a pentalenyl group, an indenyl group, a naphthyl group, an azulenyl group, an indacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isooxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran group, an indolyl group, an isoindolyl group, an indolizinyl group, a benzofuryl group, an isobenzofuryl group, an indazolyl group, a benzimidazolyl group, a benzoxazolyl group, a benzisooxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a pyridoindolyl group, a dibenzofuryl group, a phenanthridinyl group, a benzoquinolyl group, a phenazinyl group, a dibenzosilolyl group, a dibenzothiophenyl group, and a benzocarbazolyl group.

10. The condensed cyclic compound of claim 8, wherein R₁ and R₂ are each independently represented by any one of Formulae 3A to 3J below: 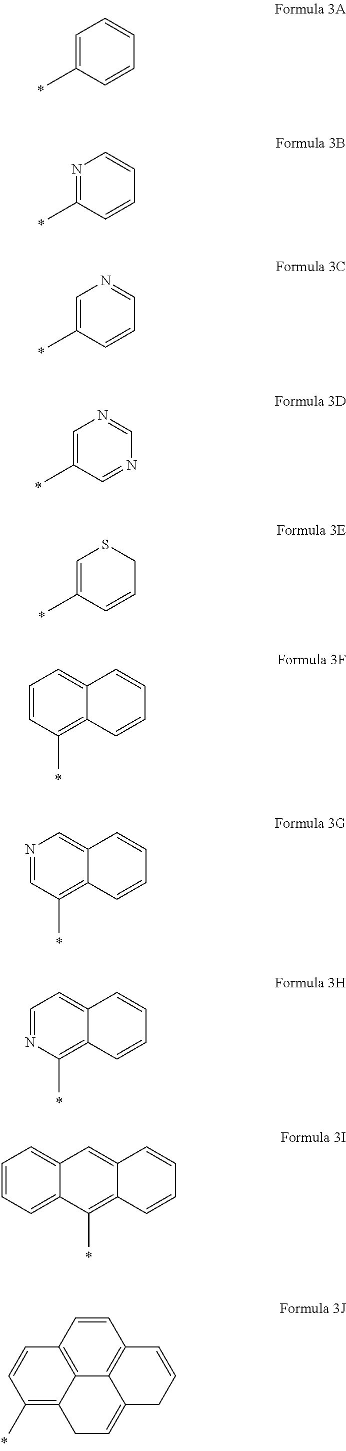
in the formulae above, * indicates a binding site.

11. The condensed cyclic compound of claim 10, wherein R₂ is represented by any one of Formulae 3A, 3F, 3I, and 3J.

12. The condensed cyclic compound of claim 8, wherein L₁ is selected from:
a direct bond, a phenylene group, a pentalenylene group, an indenylene group, a naphthylene group, an azulenylene group, an indacenylene group, an acenaphthylene group, a biphenylene group, a heptalenylene group, a phenalenylene group, a fluorenylene group, a phenanthrenylene group, an anthrylene group, a fluoranthenylene group, a pyrenylene group, a benzofluorenylene group, a naphthacenylene group, a chrysenylene group, and a triphenylenylene group.

13. The condensed cyclic compound of claim 8, wherein L₁ is a direct bond or any one represented by Formulae 5A and 5B: 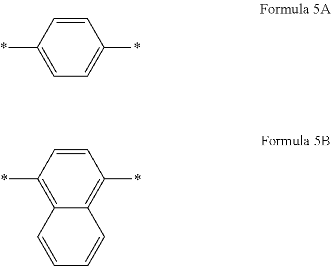 [SMILES: *c1ccc(*)cc1 ; *c1ccc(*)c2ccccc12]
in Formulae 5A and 5B, * indicates a binding site.

14. The condensed cyclic compound of claim 1, wherein the condensed cyclic compound is one of Compounds 1 to 18 below:

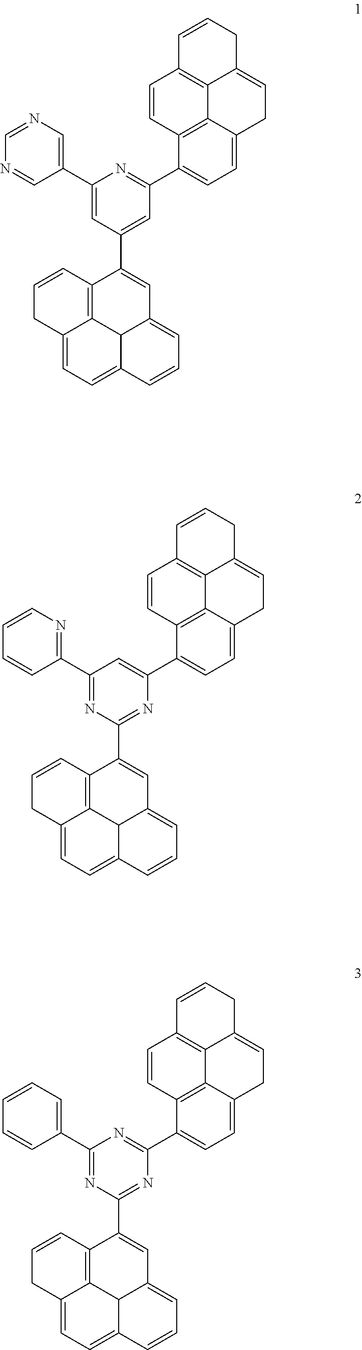 [SMILES: C1=CC2=CC=C3CC=CC4=C3C2C(=C1)C=C4c1cc(-c2cncnc2)nc(-c2ccc3c4c5c(ccc24)C=CCC5=CC3)c1 ; C1=CC2=CC=C3CC=CC4=C3C2C(=C1)C=C4c1nc(-c2ccccn2)cc(-c2ccc3c4c5c(ccc24)C=CCC5=CC3)n1 ; C1=CC2=CC=C3CC=CC4=C3C2C(=C1)C=C4c1nc(-c2ccccc2)nc(-c2ccc3c4c5c(ccc24)C=CCC5=CC3)n1]

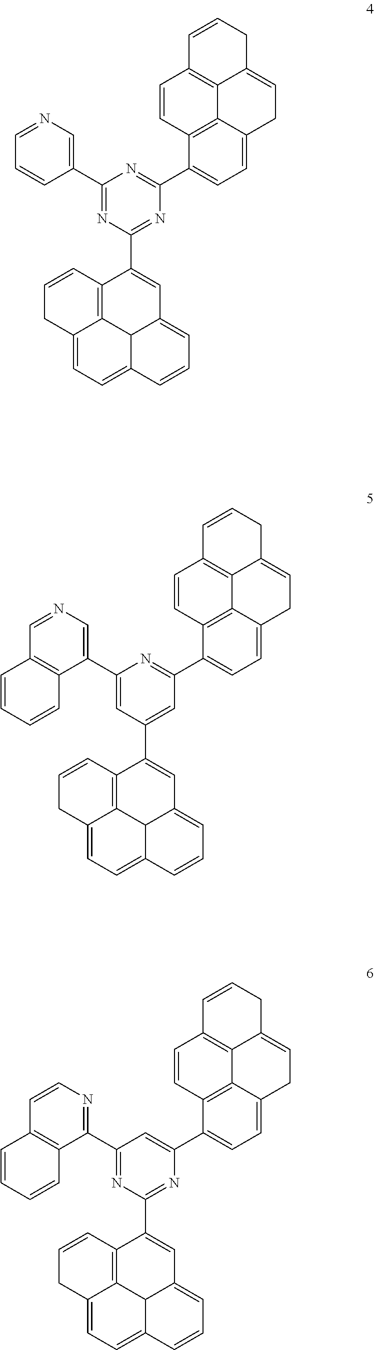 [SMILES: C1=CC2=CC=C3CC=CC4=C3C2C(=C1)C=C4c1nc(-c2cccnc2)nc(-c2ccc3c4c5c(ccc24)C=CCC5=CC3)n1 ; C1=CC2=CC=C3CC=CC4=C3C2C(=C1)C=C4c1cc(-c2cncc3ccccc23)nc(-c2ccc3c4c5c(ccc24)C=CCC5=CC3)c1 ; C1=CC2=CC=C3CC=CC4=C3C2C(=C1)C=C4c1nc(-c2nccc3ccccc23)cc(-c2ccc3c4c5c(ccc24)C=CCC5=CC3)n1]

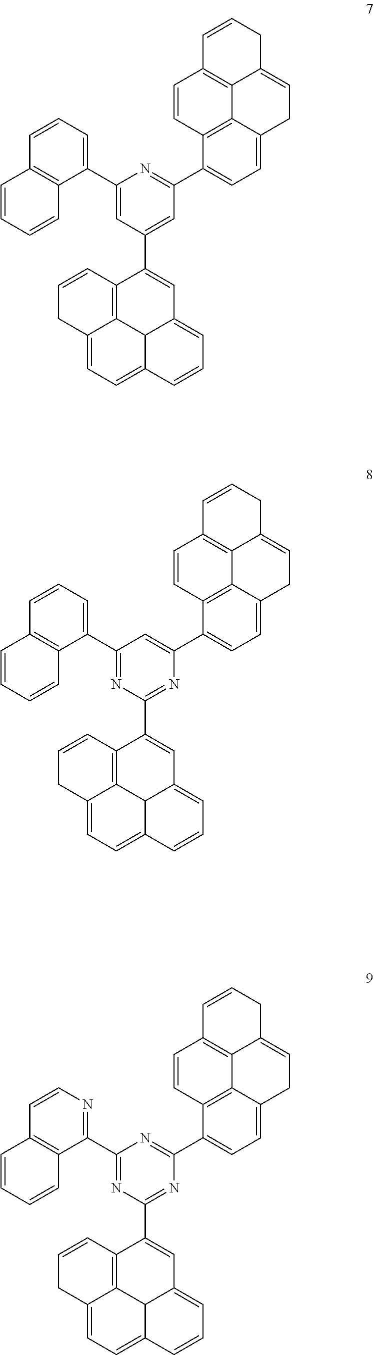 [SMILES: C1=CC2=CC=C3CC=CC4=C3C2C(=C1)C=C4c1cc(-c2cccc3ccccc23)nc(-c2ccc3c4c5c(ccc24)C=CCC5=CC3)c1 ; C1=CC2=CC=C3CC=CC4=C3C2C(=C1)C=C4c1nc(-c2cccc3ccccc23)cc(-c2ccc3c4c5c(ccc24)C=CCC5=CC3)n1 ; C1=CC2=CC=C3CC=CC4=C3C2C(=C1)C=C4c1nc(-c2nccc3ccccc23)nc(-c2ccc3c4c5c(ccc24)C=CCC5=CC3)n1]

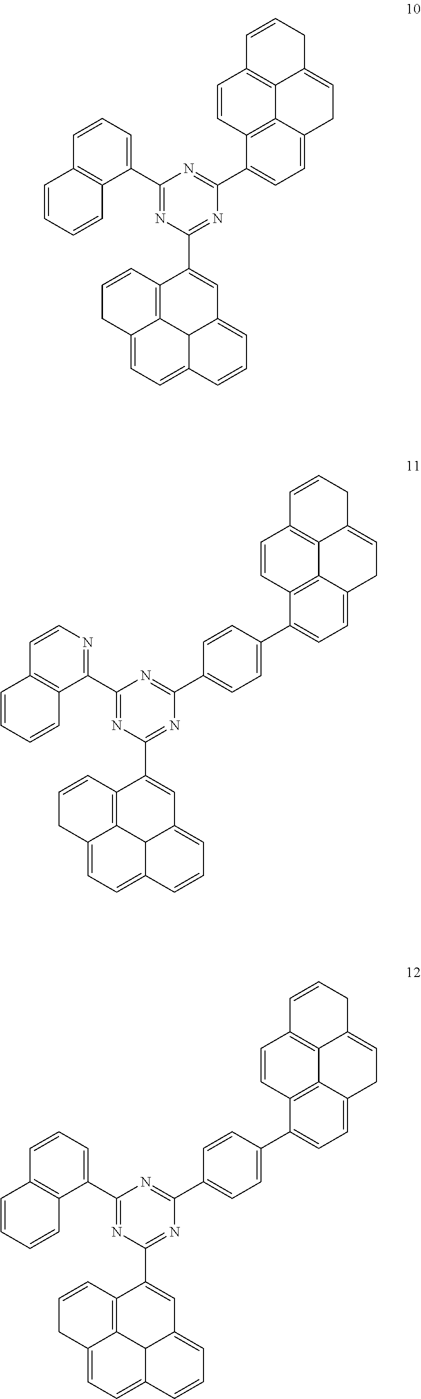 [SMILES: C1=CC2=CC=C3CC=CC4=C3C2C(=C1)C=C4c1nc(-c2cccc3ccccc23)nc(-c2ccc3c4c5c(ccc24)C=CCC5=CC3)n1 ; C1=CC2=CC=C3CC=CC4=C3C2C(=C1)C=C4c1nc(-c2ccc(-c3ccc4c5c6c(ccc35)C=CCC6=CC4)cc2)nc(-c2nccc3ccccc23)n1 ; C1=CC2=CC=C3CC=CC4=C3C2C(=C1)C=C4c1nc(-c2ccc(-c3ccc4c5c6c(ccc35)C=CCC6=CC4)cc2)nc(-c2cccc3ccccc23)n1]

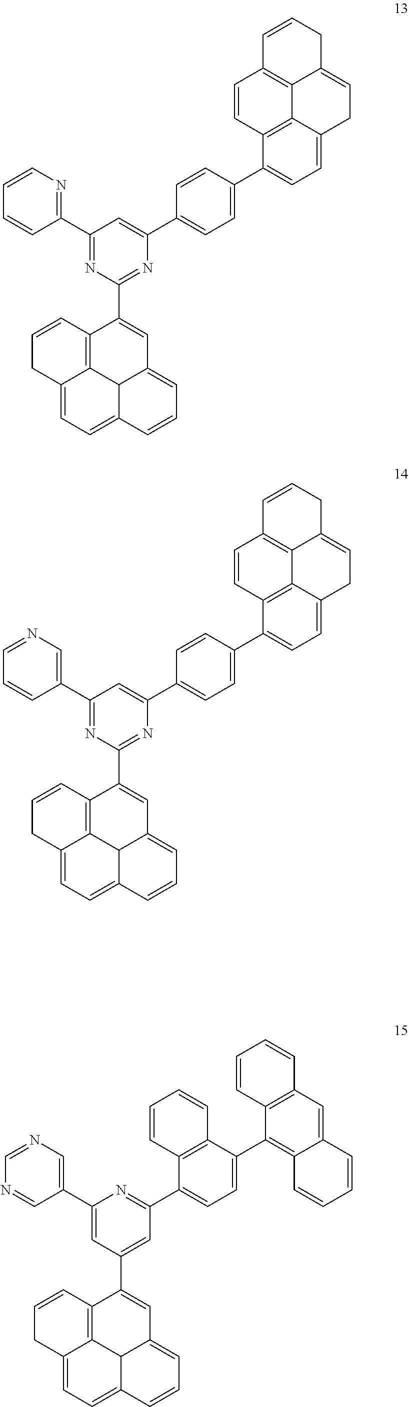 [SMILES: C1=CC2=CC=C3CC=CC4=C3C2C(=C1)C=C4c1nc(-c2ccc(-c3ccc4c5c6c(ccc35)C=CCC6=CC4)cc2)cc(-c2ccccn2)n1 ; C1=CC2=CC=C3CC=CC4=C3C2C(=C1)C=C4c1nc(-c2ccc(-c3ccc4c5c6c(ccc35)C=CCC6=CC4)cc2)cc(-c2cccnc2)n1 ; C1=CC2=CC=C3CC=CC4=C3C2C(=C1)C=C4c1cc(-c2cncnc2)nc(-c2ccc(-c3c4ccccc4cc4ccccc34)c3ccccc23)c1]

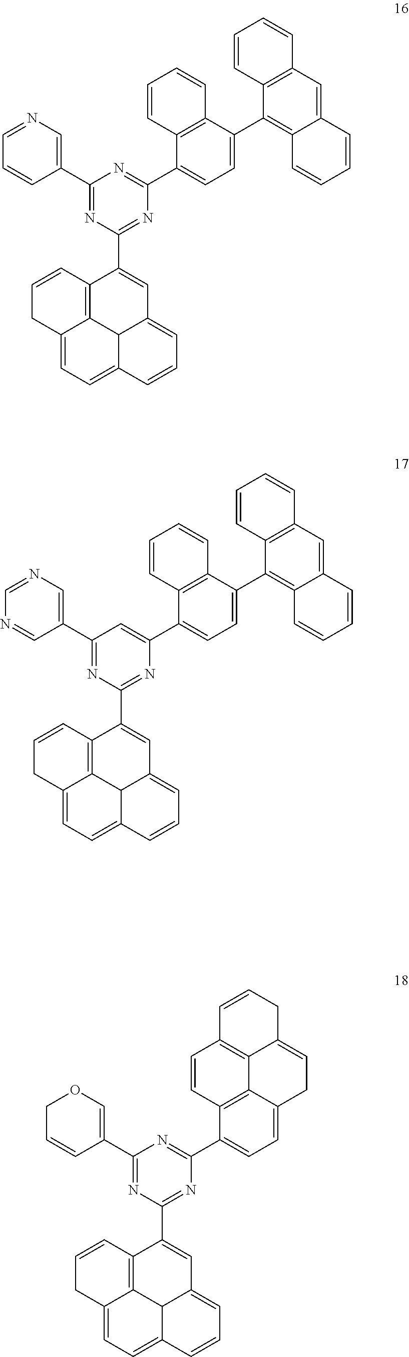 [SMILES: C1=CC2=CC=C3CC=CC4=C3C2C(=C1)C=C4c1nc(-c2cccnc2)nc(-c2ccc(-c3c4ccccc4cc4ccccc34)c3ccccc23)n1 ; C1=CC2=CC=C3CC=CC4=C3C2C(=C1)C=C4c1nc(-c2cncnc2)cc(-c2ccc(-c3c4ccccc4cc4ccccc34)c3ccccc23)n1 ; C1=CC2=CC=C3CC=CC4=C3C2C(=C1)C=C4c1nc(C2=COCC=C2)nc(-c2ccc3c4c5c(ccc24)C=CCC5=CC3)n1]

15. An organic light-emitting device comprising:
a first electrode;
a second electrode facing the first electrode; and
an organic layer between the first electrode and the second electrode,
wherein the organic layer comprises at least one of the condensed cyclic compounds of claim 1.

16. The organic light-emitting device of claim 15, wherein the organic layer comprises:
an emission layer;
a hole transport region between the first electrode and the emission layer; and
an electron transport region between the emission layer and the second electrode,
wherein the electron transport region comprises at least one of the condensed cyclic compounds.

17. The organic light-emitting device of claim 16, wherein
the electron transport region comprises an electron transport layer, and a buffer layer between the emission layer and the electron transport layer,
wherein the buffer layer comprises at least one of the condensed cyclic compounds.

18. The organic light-emitting device of claim 17, wherein
the electron transport region further comprises an electron injection layer between the electron transport layer and the second electrode.

19. The organic light-emitting device of claim 16, wherein
the hole transport region comprises at least one selected from a hole injection layer, a hole transport layer, and an electron blocking layer.

20. The organic light-emitting device of claim 16, wherein the first electrode is an anode and the second electrode is a cathode.
